(19) United States
(12) Patent Application Publication
(10) Pub. No.: US 2026/0182083 A1
(43) Pub. Date: Jun. 25, 2026

(54) TRENCH ISOLATION FOR SPAD-BASED SEMICONDUCTOR DEVICE

(71) Applicant: SEMICONDUCTOR COMPONENTS INDUSTRIES, LLC, Scottsdale, AZ (US)

(72) Inventors: Swarnal BORTHAKUR, Boise, ID (US); Andrew Eugene PERKINS, Boise, ID (US); Marc Allen SULFRIDGE, Boise, ID (US); Jeffrey Peter GAMBINO, Gresham, OR (US); Kevin MCSTAY, Hopewell Junction, NY (US); Kevin Alexander STEWART, Gresham, OR (US)

(73) Assignee: SEMICONDUCTOR COMPONENTS INDUSTRIES, LLC, Scottsdale, AZ (US)

(21) Appl. No.: 18/989,689

(22) Filed: Dec. 20, 2024

(51) Int. Cl. H10F 77/40; H10F 30/225; H10F 39/18

(52) U.S. Cl. CPC H10F 77/413; H10F 30/225; H10F 39/18

(57) ABSTRACT

A semiconductor device is disclosed. The semiconductor device includes a plurality of image pixels including a semiconductor region and a photodiode formed in the semiconductor region. Each image pixel also includes a front-side dielectric stack comprising a first metal layer disposed in a front-side dielectric and a trench extending from at least the first metal layer disposed in the front-side dielectric stack to at least an upper surface of the semiconductor region, wherein the trench includes a dielectric wall and a metal liner interior to the dielectric wall. Each image pixel also includes a passivation layer located above the semiconductor region, a back-side grid located above the passivation layer and electrically coupled to the metal liner of the trench, and a lens layer located above the passivation layer and configured to focus light into the semiconductor region.

### TECHNICAL FIELD

The disclosure relates generally to imaging systems, and particularly to imaging sensors that include single-photon avalanche diodes (SPADs) for single-photon detection.

### BACKGROUND

Modern electronic devices such as cameras, computing systems, and vehicle imaging systems, often use digital image sensors. Image sensors, which may also be referred to as imagers, may be formed from a two-dimensional array of image sensing pixels. In depth imaging applications, single-photon devices may be implemented to detect photons transmitted from a source and reflected from a target and to measure a precise target distance based on the time-of-flight (ToF) information for that photon. For example, a single-photon device may include an array of silicon photomultiplier (SiPM) devices. Each SiPM device may in turn consist of multiple single-photon avalanche diode (SPAD) based microcells. The multiple SPAD-based microcells of an SiPM device may form the light-sensitive area of the SiPM and may provide an analog output signal.

In an SiPM, incident photons may cause the generation of highly accelerated electrons due to the large electric fields present in a biased SPAD-based microcell. The inventors of embodiments of the present disclosure have recognized that such highly accelerated electrons may generate secondary photons. The inventors of embodiments of the present disclosure have also recognized that transmission of such secondary photons into an adjacent microcell may falsely trigger an avalanche breakdown in the adjacent microcell, thereby causing an erroneous signal and unwanted crosstalk. Embodiments of the present disclosure may address one or more of these challenges.

### BRIEF DESCRIPTION OF THE DRAWINGS

A more complete understanding of the present embodiments may be acquired by referring to the following description taken in conjunction with the accompanying drawings, in which like reference numbers indicate like features.

FIG. 1 illustrates a circuit diagram showing an example single-photon avalanche diode (SPAD) device in accordance with embodiments of the present disclosure.

FIG. 2 illustrates a circuit diagram of an example silicon photomultiplier in accordance with embodiments of the present disclosure.

FIG. 3 illustrates a block diagram of a pixel array and associated readout circuitry for reading out image signals in an example SPAD-based semiconductor device in accordance with embodiments of the present disclosure.

FIG. 4 illustrates a schematic block diagram of an example imaging system with a SPAD-based semiconductor device in accordance with embodiments of the present disclosure.

FIG. 5A illustrates a side cross-sectional view of an image pixel in accordance with embodiments of the present disclosure.

FIG. 5B illustrates a bottom view of an image pixel in accordance with embodiments of the present disclosure.

FIGS. 6A-6I illustrate side cross-sectional views of an image pixel at different stages of back-side processing utilized to form the image pixel in accordance with embodiments of the present disclosure.

FIGS. 7A-7I illustrate side cross-sectional views of an image pixel at different stages of back-side processing utilized to form the image pixel in accordance with embodiments of the present disclosure.

FIGS. 8A-8E illustrate side cross-sectional views of an image pixel at different stages of back-side processing utilized to form the image pixel in accordance with embodiments of the present disclosure.

FIG. 9 illustrates a side cross-sectional view of an image pixel in accordance with embodiments of the present disclosure.

FIG. 10 illustrates a side cross-sectional view of an image pixel in accordance with embodiments of the present disclosure.

FIG. 11 illustrates a side cross-sectional view of an image pixel in accordance with embodiments of the present disclosure.

FIG. 12 illustrates a side cross-sectional view of an image pixel in accordance with embodiments of the present disclosure.

FIGS. 13A-13C illustrate side cross-sectional views of an image pixel at different stages of back-side processing utilized to form the image pixel in accordance with embodiments of the present disclosure.

FIG. 14 illustrates a side cross-sectional view of an image pixel in accordance with embodiments of the present disclosure.

FIGS. 15A-15F illustrate side cross-sectional views of an image pixel at different stages of back-side processing utilized to form the image pixel in accordance with embodiments of the present disclosure.

FIG. 16 illustrates a side cross-sectional view of an image pixel in accordance with embodiments of the present disclosure.

### DETAILED DESCRIPTION

Details of one or more embodiments are set forth in the description below and the accompanying drawings. Other features will be apparent from the description, drawings, and from the claims. The embodiments disclosed should not be interpreted, or otherwise used, as limiting the scope of the disclosure, including the claims. In addition, one skilled in the art understands that the following description has broad application, and the discussion of any embodiment is meant to be exemplary of that embodiment, and not intended to intimate that the scope of the disclosure, including the claims, is limited to that embodiment.

Various terms are used to refer to particular system components. Different companies may refer to a component by different names, and this disclosure does not intend to distinguish between components that differ in name but not form and function. In the following discussion and in the claims, the terms “including” and “comprising” are used in an open-ended fashion, and thus should be interpreted to mean “including, but not limited to.” Also, the term “couple” or “coupled” is intended to mean either an indirect or direct connection. Thus, if a first device couples to, or is coupled to, a second device, that connection between the first device and the second device may be through a direct connection or through an indirect connection via other devices and connections.

Terms defining an elevation, such as “above,” “below,” “upper,” and “lower,” shall be locational terms in reference to a direction of light incident upon a pixel array and/or an image pixel. Unless otherwise specified, light entering shall be considered to interact with or pass objects and/or structures that are “above” and “upper” before interacting with or passing objects and/or structures that are “below” or “lower.” Thus, the locational terms may not have any relationship to the direction of the force of gravity.

Imaging systems may include image sensors that sense light by converting impinging photons of light into pairs of electrons and holes that are integrated or collected in pixel photodiodes within the sensor array. After completion of an integration cycle, collected charge may be converted into a voltage, which may be supplied to the output terminals of the sensor. In complementary metal-oxide semiconductor (CMOS) image sensors, the charge to voltage conversion may be accomplished directly in the pixels themselves and the analog pixel voltage may be transferred to the output terminals through various pixel addressing and scanning schemes. The analog pixel voltage can also be later converted on-chip to a digital equivalent and processed in the digital domain.

In other image sensing applications, a photodiode may be implemented with a single-photon avalanche diode (SPAD). In SPAD-based devices, the photon detection principle is different than in CMOS image sensors. The single-photon avalanche diode may be biased slightly above its reverse breakdown voltage, and when an incident photon generates an electron and hole pair, the electron or hole carrier may drift to the multiplication region where it may initiate an avalanche breakdown with additional carriers being generated. The avalanche multiplication may produce a current signal that may be detected by readout circuitry associated with the single-photon avalanche diode. The avalanche process may subsequently be stopped or quenched by lowering the bias below or equal to the reverse breakdown voltage of the diode. Each single-photon avalanche diode may therefore include a passive and/or active quenching circuit for quenching the avalanche by lowering the bias.

SPAD devices may be used in multiple ways. For example, in low light level applications, the arriving photons may simply be counted. As another example, SPAD devices may be used to measure photon time-of-flight (ToF) from a synchronized light source to a scene object point and back to the sensor, which may be used to obtain a three-dimensional image of the scene.

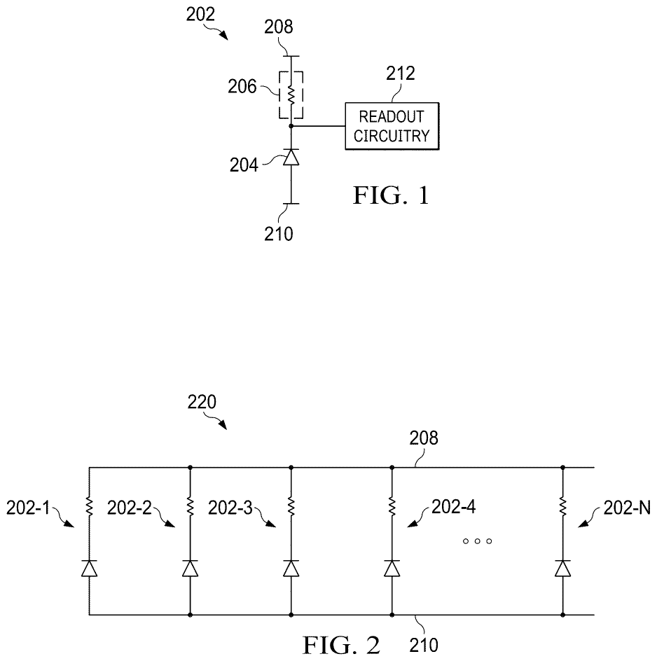

FIG. 1 illustrates a circuit diagram showing an example single-photon avalanche diode (SPAD) device 202 in accordance with embodiments of the present disclosure. As shown in FIG. 1, SPAD device 202 may include single-photon avalanche diode 204 that may be coupled in series with quenching circuitry 206 between a first supply voltage terminal 208 and a second supply voltage terminal 210. In some embodiments, the first supply voltage terminal 208 may be a positive power supply voltage terminal, and the second supply voltage terminal 210 may be a ground power supply voltage terminal. During operation of SPAD device 202, first supply voltage terminal 208 and second supply voltage terminal 210 may be used to bias single-photon avalanche diode 204 to a voltage that is higher than the reverse breakdown voltage of single-photon avalanche diode 204. For the purposes of the present disclosure, the reverse breakdown voltage in Geiger mode may refer to the reverse voltage that can sustain avalanche breakdown in the avalanche diode without needs of additional charge carriers. When single-photon avalanche diode 204 is biased above the reverse breakdown voltage in this manner, absorption of a single-photon may trigger a large, but short-duration, avalanche current through impact ionization.

Quenching circuitry 206 may be used to lower the bias voltage of single-photon avalanche diode 204 below the level of the reverse breakdown voltage. For the purposes of the present disclosure, quenching circuitry 206 may also be referred to as quenching element 206. Lowering the bias voltage of single-photon avalanche diode 204 below the reverse breakdown voltage may stop the avalanche process and corresponding avalanche current. The embodiment of quenching circuitry 206 shown in FIG. 1 illustrates an example where a resistor is used to implement passive quenching circuitry that may, without external control or monitoring, automatically quench the avalanche current once initiated. After the avalanche is initiated, the resulting current rapidly discharges the capacity of the device, lowering the voltage at single-photon avalanche diode 204 to near to the reverse breakdown voltage. The resistance associated with the resistor in quenching circuitry 206 may result in the final current being lower than required to sustain avalanche. Single-photon avalanche diode 204 may then be reset to above the reverse breakdown voltage to enable detection of another photon.

Although the example embodiment of quenching circuitry 206 shown in FIG. 1 utilizes a resistor to implement passive quenching circuitry, other embodiments may utilize active quenching circuitry. Active quenching circuitry may modulate the quench resistance. For example, before a photon is detected, the quench resistance may be set high. Once a photon is subsequently detected and the avalanche is quenched, the quench resistance may be lowered to reduce recovery time. Such active quenching circuitry may reduce the time it takes for SPAD device 202 to be reset. Accordingly, active quenching circuitry may allow SPAD device 202 to detect incident light at a faster rate than when passive quenching circuitry is used, improving the dynamic range of the SPAD device.

SPAD device 202 may also include readout circuitry 212. Readout circuitry 212 may be formed in any of numerous ways to obtain information from SPAD device 202. For example, readout circuitry 212 may include a pulse counting circuit that counts arriving photons. Alternatively, or in addition, readout circuitry 212 may include time-of-flight circuitry that may be used to measure photon time-of-flight (ToF). The photon time-of-flight information may be used to perform depth sensing.

In some embodiments, photons may be counted by an analog counter to form the light intensity signal as a corresponding pixel voltage. Readout circuitry may also include amplification circuitry and/or digital pulse counting circuits. The ToF signal may also be obtained by converting the time of photon flight to a voltage.

Readout circuitry 212 may be coupled to any suitable portion of SPAD device 202 to read single-photon avalanche diode 204. For example, as shown in FIG. 1, readout circuitry 212 may be coupled to a node between single-photon avalanche diode 204 and quenching circuitry 206. In some embodiments, quenching circuitry 206 may be considered as integral with readout circuitry 212.

Because SPAD devices can detect a single incident photon of light, SPAD devices may be effective at imaging scenes with low light levels. Each SPAD device may detect how many photons are received within a given period of time. However, as discussed above, each time a photon is received and an avalanche current initiated, the SPAD device must be quenched and reset before being ready to detect another photon. As incident light levels increase, the dynamic range of the SPAD device may be limited by the reset time. For example, once incident light levels exceed a given level, the SPAD device may be triggered immediately upon being reset. To increase the dynamic range, multiple SPAD devices may be grouped together as described below with reference to the example embodiment illustrated in FIG. 2.

FIG. 2 illustrates a circuit diagram of an example silicon photomultiplier (SiPM) 220 in accordance with embodiments of the present disclosure. As shown in FIG. 2, SiPM 220 may include a group of N number of SPAD devices 202, including for example SPAD devices 202-1, 202-2, 202-3, 202-4, through 202-N. An SiPM such as SiPM 220 may be implemented with any suitable number of SPAD devices 202. For example, an SiPM such as SiPM 220 may be implemented with ten, one hundred, one thousand, or more SPAD devices 202. For the purposes of the present disclosure, SPAD devices such as SPAD devices 202 may also be referred to as SPAD pixels, SPAD-based image pixels, or image pixels.

Although not shown explicitly in FIG. 2, readout circuitry for SiPM 220 may measure the combined output current from all of SPAD-based image pixels 202 in SiPM 220. In this way, the dynamic range of an imaging system including the multiple SPAD-based image pixels 202 of SiPM 220 may be increased. For example, each individual instance of SPAD-based image pixel 202 in SiPM 220 may have an associated probability of an avalanche current being triggered when an incident photon is received. The probability of the avalanche current being triggered depends on both a first probability of an electron being created when a photon reaches the diode as well as a second probability of the electron triggering an avalanche current. The total probability of a photon triggering an avalanche current may be referred to as the photon-detection efficiency (PDE) of the SPAD-based image pixel. By grouping together multiple SPAD-based image pixels 202 in SiPM 220, a more accurate measurement of the incoming incident light may be provided.

In some applications, it may be desirable to use SPAD-based image pixels to obtain image data across an array to allow a higher resolution reproduction of the imaged scene. In such cases, SPAD-based image pixels in a single imaging system may have per-pixel readout capabilities. Alternatively, an array of SiPMs, each including multiple SPAD-based image pixels, may be included in the imaging system. The outputs from each pixel or from each SiPM may be used to generate image data for an imaged scene. The array may be capable of independent detection, whether using a single SPAD-based image pixel or a plurality of SPAD-based image pixels in a line array (for example, an array having a single row and multiple columns or a single column and multiple rows) or an array having more than ten, more than one hundred, or more than one thousand rows and/or columns.

Although there may be numerous different use cases for SPAD-based image pixels as discussed above, the underlying technology used to detect incident light may be the same or similar for the different applications of the SPAD-based image pixels. Regardless of their application, semiconductor devices that utilize SPAD-based image pixels may thus be collectively referred to as SPAD-based semiconductor devices. For example, an SiPM with a plurality of SPAD-based image pixels having a common output may be referred to as a SPAD-based semiconductor device. Similarly, an array of SPAD-based image pixels with per-pixel readout capabilities may also be referred to as a SPAD-based semiconductor device. Further, an array of SiPMs with per-SiPM readout capabilities may likewise be referred to as a SPAD-based semiconductor device.

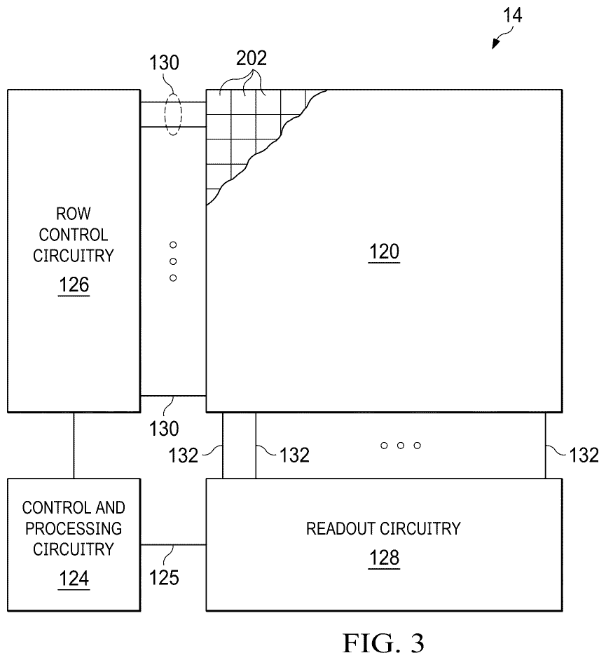

FIG. 3 illustrates a block diagram of a pixel array and associated readout circuitry for reading out image signals in an example SPAD-based semiconductor device 14 in accordance with embodiments of the present disclosure. As shown in FIG. 3, SPAD-based semiconductor device 14 may include an array 120 of SPAD-based image pixels 202 arranged in rows and columns. Array 120 may contain, for example, hundreds or thousands of rows and columns of SPAD-based image pixels 202.

In some embodiments, each SPAD-based image pixel 202 may be coupled to an analog pulse counter, for example, which may generate a corresponding pixel voltage based on received photons. In other embodiments, each SPAD-based image pixel 202 may be coupled to a digital pulse counter whose digital output code may correspond to the number of photons in a defined time window. Each SPAD-based image pixel 202 may additionally or alternatively be coupled to a time-of-flight to voltage converter circuit. In both types of readout circuits, voltages may be stored on pixel capacitors and may later be scanned in a row-by-row fashion. In the case of an SiPM device, both types of readout circuits may be coupled to the output of image pixel, which may be formed by multiple SPAD-based microcells and connected together to form the single output pixel.

Control and processing circuitry 124 may be coupled to row control circuitry 126 and readout circuitry 128. Readout circuitry 128 may also be referred to as column control circuitry, column decoder circuitry, processing circuitry, or image readout circuitry. Row control circuitry 126 may receive row addresses from control and processing circuitry 124 and supply corresponding row control signals to SPAD-based image pixels 202 over row control paths 130. One or more conductive lines such as column lines 132 may be coupled to each column of SPAD-based image pixels 202 in array 120. Column lines 132 may be used for reading out image signals from SPAD-based image pixels 202 and for supplying bias signal, such as bias voltages and/or bias currents, to SPAD-based image pixels 202. During pixel readout operations, a pixel row in array 120 may be selected using row control circuitry 126 and image signals generated by SPAD-based image pixels 202 in that pixel row may be read out along column lines 132.

Readout circuitry 128 may receive analog or digital image signals from SPAD-based image pixels 202 over column lines 132. Readout circuitry 128 may include sample-and-hold circuitry for sampling and temporarily storing image signals read out from array 120, amplifier circuitry, analog-to-digital conversion (ADC) circuitry, time-to-digital conversion (TDC) circuitry, bias circuitry, column memory, latch circuitry for selectively enabling or disabling the column circuitry, or other circuitry that is coupled to one or more columns of pixels in array 120 for operating SPAD-based image pixels 202 and for reading out signals from SPAD-based image pixels 202. ADC circuitry in readout circuitry 128 may convert analog pixel values received from array 120 into corresponding digital pixel values, which may also be referred to as digital image data or digital pixel data. Alternatively, ADC circuitry may be incorporated into each SPAD-based image pixel 202. Readout circuitry 128 may supply digital pixel data to control and processing circuitry 124 via path 125 for pixels in one or more pixel columns.

The example of SPAD-based semiconductor device 14 having readout circuitry to read out signals from the SPAD-based image pixels in a row-by-row manner is merely illustrative. In other embodiments, the readout circuitry in the image sensor may simply include digital pulse counting circuits coupled to each SPAD-based image pixel. Any other desired readout circuitry arrangement may be used.

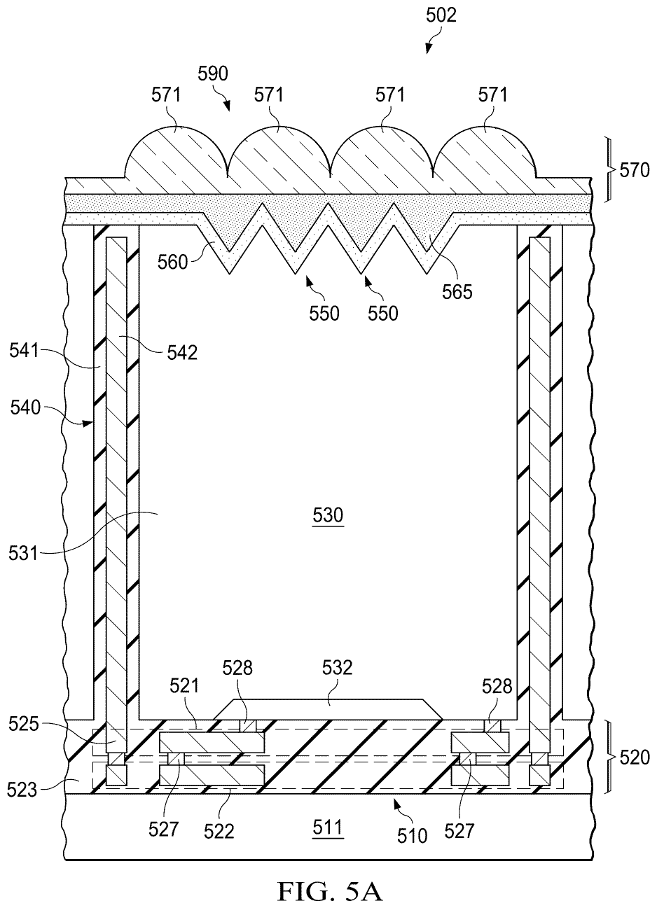

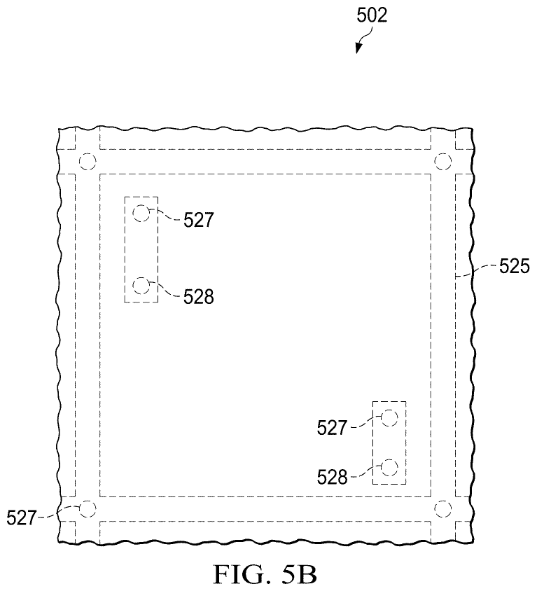

As described in further detail below with reference to FIGS. 5A-16, each SPAD-based image pixel 202 in array 120 may be a back-side illuminated (BSI) SPAD-based image pixel. In some embodiments, array 120 may be part of a multi-die arrangement in which SPAD-based image pixels 202 may be formed in a first substrate and some or all of the corresponding control and readout circuitry may be formed in a second substrate. Further, it should be understood that instead of having an array 120 of SPAD-based image pixels 202 as shown by the example embodiment in FIG. 3, SPAD-based semiconductor device 14 may instead have an array of SiPMs that may each include multiple SPAD-based image pixels 202 with a common output.

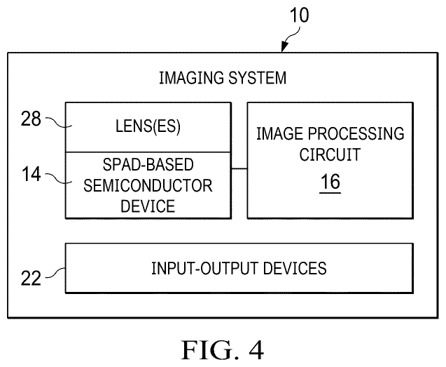

SPAD-based semiconductor devices such as SPAD-based semiconductor device 14 may be utilized in numerous different imaging applications. As described below with reference to FIG. 4, SPAD-based semiconductor device 14 may be used in, for example, LIDAR imaging applications.

FIG. 4 illustrates a schematic block diagram of imaging system 10 with SPAD-based semiconductor device 14 in accordance with embodiments of the present disclosure. In some embodiments, imaging system 10 may be an electronic device such as a digital camera, a computer, a cellular telephone, a medical device, or other electronic device. Imaging system 10 may also be an imaging system of a vehicle. In some embodiments, imaging system 10 may be used for LIDAR applications. Imaging system 10 may include one or more SPAD-based semiconductor devices 14, which may also be referred to as devices, semiconductor devices, image sensors, or SPAD-based image sensors. One or more lenses 28 may optionally cover each SPAD-based semiconductor device 14. During operation, lenses 28 may focus light onto one or more SPAD-based semiconductor device 14. SPAD-based semiconductor device 14 may include SPAD-based image pixels that may convert incident light into digital data. SPAD-based semiconductor device 14 may have any suitable number of SPAD-based image pixels, such as one hundred, one thousand, one million, or more.

SPAD-based semiconductor device 14 may optionally include additional circuitry. For example, SPAD-based semiconductor device 14 may include bias circuitry such as source follower load circuits. As other examples, SPAD-based semiconductor device 14 may also include one or more of sample and hold circuitry, amplifier circuitry, analog-to-digital converter (ADC) circuitry, time-to-digital converter (TDC) circuitry, data output circuitry, address circuitry, and/or buffer circuitry and memory.

SPAD-based semiconductor device 14 may be communicatively coupled to image processing circuit 16. Image data from SPAD-based semiconductor device 14 may thus be provided to image processing circuit 16. Image processing circuit 16 may perform image processing functions including, but not limited to, automatic focusing functions, depth sensing, data formatting, adjusting white balance and exposure, implementing video image stabilization, and/or face detection. For example, during automatic focusing operations, image processing circuit 16 may process data gathered by the SPAD-based image pixels to determine the magnitude and direction of movement of lens 28 needed to bring an object of interest into focus. Image processing circuit 16 may process data gathered by the SPAD pixels to determine a depth map of the scene.

Imaging system 10 may provide a user with numerous high-level functions. In a computer or advanced cellular telephone, for example, a user may be provided with the ability to run user applications. To implement these functions, imaging system 10 may include input-output devices 22 such as keypads, buttons, input-output ports, joysticks, and/or displays. Additional storage and processing circuitry such as volatile and nonvolatile memory, microprocessors, microcontrollers, digital signal processors, application specific integrated circuits, and/or other processing circuits may also be included in imaging system 10.

Input-output devices 22 may include output devices that work in combination with SPAD-based semiconductor device 14. For example, a light-emitting component may be included in the imaging system to emit light, such as infrared light or light of any other desired type. SPAD-based semiconductor device 14 may measure the reflection of the light off of an object to measure distance to the object in a light detection and ranging (LIDAR) scheme.

FIG. 5A illustrates a side cross-sectional view of image pixel 502 in accordance with embodiments of the present disclosure. Image pixel 502 may be a SPAD-based image pixel and may also be referred to as SPAD-based image pixel 502. Although a single instance of image pixel 502 is illustrated in FIG. 5, image pixel 502 may be one of a plurality of image pixels in an array. For example, image pixel 502 may represent an embodiment of each of the plurality of SPAD-based image pixels 202 in array 120 of SPAD-based semiconductor device 14 described above with reference to FIG. 3. And in embodiments where SPAD-based semiconductor device 14 is implemented with an array of SiPMs, multiple instances of SPAD-based image pixel 502 may be grouped together to form each SiPM in the array.

Image pixel 502 may include front-side dielectric stack 520, semiconductor region 530, trench 540, a plurality of scattering structures 550 formed at an upper surface of semiconductor region 530, passivation layer 560, buffer layer 565, and lens layer 570. Image pixel 502 may be a back-side illuminated image pixel. For example, during manufacture, various semiconductor processing steps may be applied to the front side 510 of semiconductor region 530. Semiconductor region 530 may have initially been formed from an epitaxial growth on a silicon substrate. A photodiode may then be formed in semiconductor region 530. In some embodiments, the photodiode may be a single-photon avalanche diode. Doping may be added to semiconductor region 530 to form a photodiode, or specifically, a single-photon avalanche diode. For example, semiconductor region 530 may include an n-type doping region 532 within a p-type epitaxial region 531. The single-photon avalanche diode may be formed by the p-n junction of the p-type epitaxial region 531 and n-type doping region 532. Further semiconductor processing steps may then be applied to the front side 510 of semiconductor region to form, for example, front-side dielectric stack 520 and trench 540.

Subsequently, front side 510 may be stacked on an additional substrate 511, which may provide structural support and/or may include corresponding control and readout circuitry to which the metal routing in front-side dielectric stack 520 may be coupled. Additional processing may then be applied to the back side 590 of semiconductor region 530 to form a plurality of scattering structures 550 at an upper surface of semiconductor region 530, as well as passivation layer 560, buffer layer 565, and lens layer 570.

Front-side dielectric stack 520 may comprise at least a first metal layer 521 and a second metal layer 522 disposed in a front-side dielectric 523. Front-side dielectric 523 may include a dielectric material such as silicon dioxide. First metal layer 521 and second metal layer 522 may include patterned metal lines that may be used for signal routing and for electrically coupling to the single-photon avalanche diode within semiconductor region 530. Vias 527 may couple metal lines on first metal layer 521 to metal lines on second metal layer 522. Contacts 528 may couple metal lines on first metal layer 521 to portions of semiconductor region 530. Metal lines formed in first metal layer 521 and second metal layer 522, as well as the vias 527 and the contacts 528 coupling different metal lines to the p-type epitaxial region 531 and n-type doping region 532 of semiconductor region 530, may be used to provide electrical biasing to the single-photon avalanche diode.

As described below with reference to FIG. 5B, the metal lines on first metal layer 521 may form a front-side grid 525 around image pixel 502 from a bottom view perspective. FIG. 5B illustrates a bottom view of image pixel 502 in accordance with embodiments of the present disclosure. Specifically, FIG. 5B illustrates a bottom view of image pixel 502 at the level of first metal layer 521. As shown in FIG. 5B, the metal lines on first metal layer 521 may form front-side grid 525 surrounding the interior of image pixel 502 from the bottom view perspective. Further instances of image pixel 502 may be repeated to the sides of the image pixel 502 shown in FIG. 5B, with adjacent instances of image pixel 502 sharing bordering portions of front-side grid 525.

Returning to FIG. 5A, image pixel 502 may include a plurality of scattering structures 550 formed at an upper surface of the semiconductor region 530. Scattering structures 550 may form a plurality of shallow trenches in the upper surface of semiconductor region 530. The refractive index of semiconductor region 530 on the bottom side of scattering structures 550 may be different than the refractive index of passivation layer 560 and buffer layer 565 on the upper side of scattering structures 550. Scattering structures 550 may thus be configured to scatter incident light as the light passes through scattering structures 550. Such scattering of incident light may increase the length of the path of the light as the light travels through semiconductor region 530, thereby increasing the probability of the incident light being absorbed within semiconductor region 530. Such scattering may be particularly helpful for incident light of higher wavelengths, such as near infrared light.

Passivation layer 560 may be located above semiconductor region 530. For example, passivation layer 560 may be located on the upper surface of semiconductor region 530, including on the upper surface of the scattering structures 550 formed at the upper surface of semiconductor region 530. Passivation layer 560 may be formed with a high-k dielectric. For example, passivation layer 560 may include layers of one or more of aluminum oxide, hafnium oxide, and/or tantalum oxide. From an optical standpoint, passivation layer 560 may also improve the passage of light into semiconductor region 530. Specifically, passivation layer 560 may provide an intermediate refractive index between buffer layer 565 and semiconductor region 530, thereby improving the passage of light into semiconductor region 530 and reducing the reflection of light at the border of semiconductor region 530.

Buffer layer 565 may be located above passivation layer 560. The buffer layer 565 may be a part of an overall passivation layer 560. Alternatively, the buffer layer 565 may be separate from the passivation layer 560 in form and/or function. In embodiments of image pixel 502 including scattering structures 550, buffer layer 565 may have a lower surface that fills in the trenches of the plurality of scattering structures 550 and a planar upper surface. In other embodiments of image pixel 502 that may omit scattering structures 550, the lower surface of buffer layer 565 may be a planar to match a planar profile of the upper surface of semiconductor region 530 and passivation layer 560. In some embodiments, buffer layer 565 may be formed with an oxide material such as silicon dioxide.

Lens layer 570 may be located above buffer layer 565 and passivation layer 560. In some embodiments, lens layer 570 may include one or more microlenses 571. Microlenses 571 may be formed with either an organic or an inorganic material. For example, microlenses 571 may in some embodiments be formed with an inorganic oxide material. In other embodiments, microlenses 571 may be formed with an organic material, such as an acrylic-based polymer. The upper surface of each microlens 571 may have a spherical convex shape. Microlenses 571 may thus refract the light received by image pixel 502 and focus that light into underlying elements of image pixel 502.

As shown in FIG. 5A, image pixel 502 may also include trench 540. Trench 540 may be formed with a similar pattern as front-side grid 525 surrounding the interior of image pixel 502 from a top view or bottom view perspective.

During manufacture of image pixel 502, trench 540 may be formed, for example, by an etch and fill process from the front side 510 prior to the formation of front-side dielectric stack 520. Trench 540 may include dielectric wall 541 and metal liner 542 interior to dielectric wall 541. For example, after an etch process, a dielectric material may be deposited to form dielectric wall 541 along the edges of the etched area. Metal liner 542 may then be deposited interior to dielectric wall 541. The dielectric material forming dielectric wall 541 may include, for example, silicon dioxide. Dielectric wall 541 may thus electrically isolate one instance of image pixel 502 from neighboring instances of image pixel 502 in an array. In some embodiments, metal liner 542 may be formed with a reflective metal such as copper. In other embodiments, metal liner 542 may be formed with an absorptive metal such as tungsten. Whether by reflection or absorption, metal liner 542 may prevent photons of light from passing through one instance of image pixel 502 to a neighboring instance of image pixel 502, thereby reducing or eliminating unwanted optical crosstalk between neighboring instances of image pixel 502. Specifically, metal liner 542 of trench 540 may prevent secondary photons generated during the avalanche from passing into a neighboring image pixel. As shown in FIG. 5A, metal liner 542 may extend to first metal layer 521. Metal liner 542 of trench 540 may thus be electrically coupled via metal lines on first metal layer 521 to ground, for example, along with front-side grid 525, to reduce dark current generation.

As described above, a single-photon avalanche diode may be formed by the p-n junction of the p-type epitaxial region 531 and the n-type doping region 532 and may be biased during operation above the reverse breakdown voltage of the single-photon avalanche diode. When an incident photon generates an electron and hole pair, the electron or hole carrier may drift to the multiplication region where it may initiate an avalanche breakdown with additional carriers being generated. Due to the high electric fields near the multiplication region, highly accelerated electron carriers may generate secondary photons. If transmitted to a neighboring image pixel, such secondary photons may trigger an avalanche breakdown in the neighboring image pixel resulting in an erroneous readout. To reduce such cross-talk, trench 540 may block certain paths through which a secondary photon generated in semiconductor region 530 may otherwise travel to a neighboring image pixel. For example, by surrounding the sides of semiconductor region 530, trench 540 may prevent secondary photons from travelling from semiconductor region 530 of image pixel 502 to the semiconductor region of a neighboring image pixel. Similarly, by extending down to first metal layer 521, trench 540 and particularly metal liner 542 may block secondary photons from reflecting off metal lines within first metal layer 521 and traveling through front-side dielectric stack 520 to the semiconductor region of a neighboring image pixel.

The secondary crosstalk of various examples of image pixels disclosed herein may also be further improved by providing additional structures that may block secondary photons from reflecting off and/or traveling through the lens layer located above the semiconductor region 530. For example, some embodiments may include a back-side grid that may be located above the buffer layer and may be coupled to the metal liner of the trench. In some embodiments, a metal contact may couple the back-side grid to the metal liner of the trench. The back-side grid and the metal contact may be formed with an absorptive metal such as tungsten. The back-side grid and metal contact may thus block secondary photons from reflecting off and/or traveling through the lens layer located above the semiconductor region and into a neighboring image pixel.

In some embodiments, the trench may extend above an upper surface of the semiconductor region, and the lens layer may be located in a recess between opposing areas of the trench. The lens layer may thus be located at least in part below a level of the back-side grid. The trench, as well as the metal contact coupling a metal liner of the trench to the back-side grid, may thus prevent secondary photons from reflecting off and/or traveling through the lens layer located above the semiconductor region and into a neighboring image pixel.

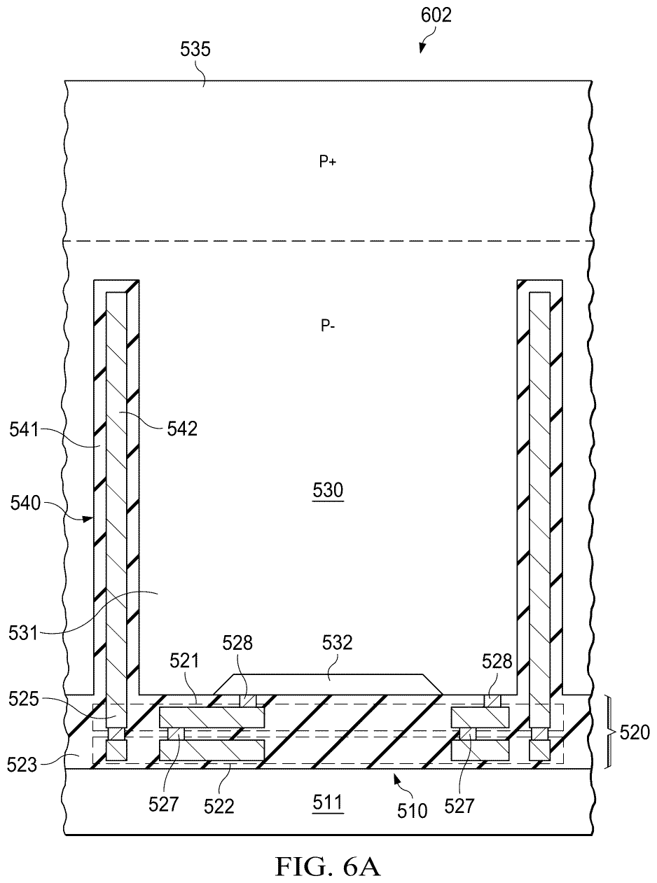

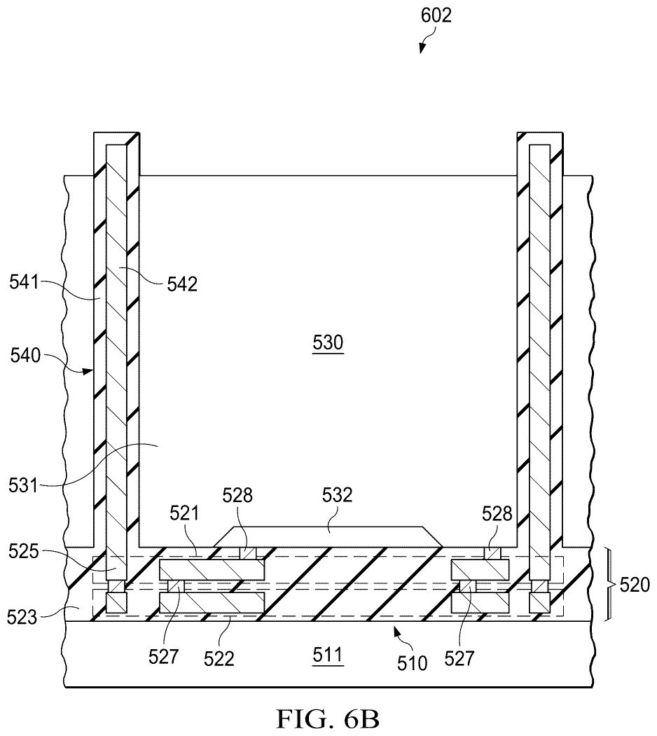

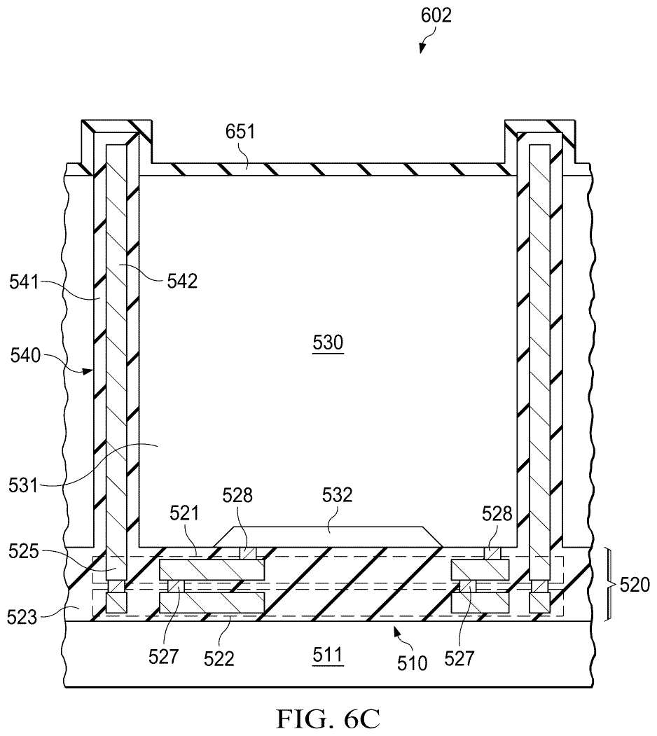

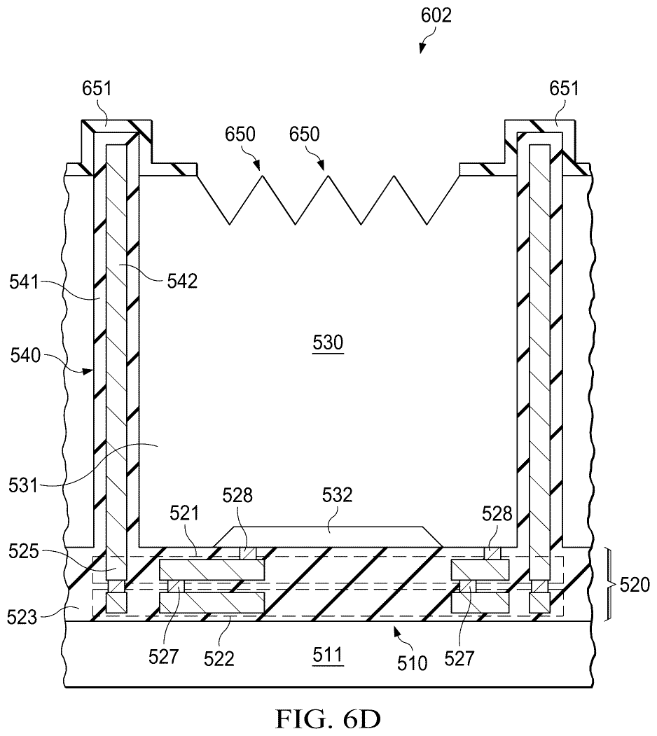

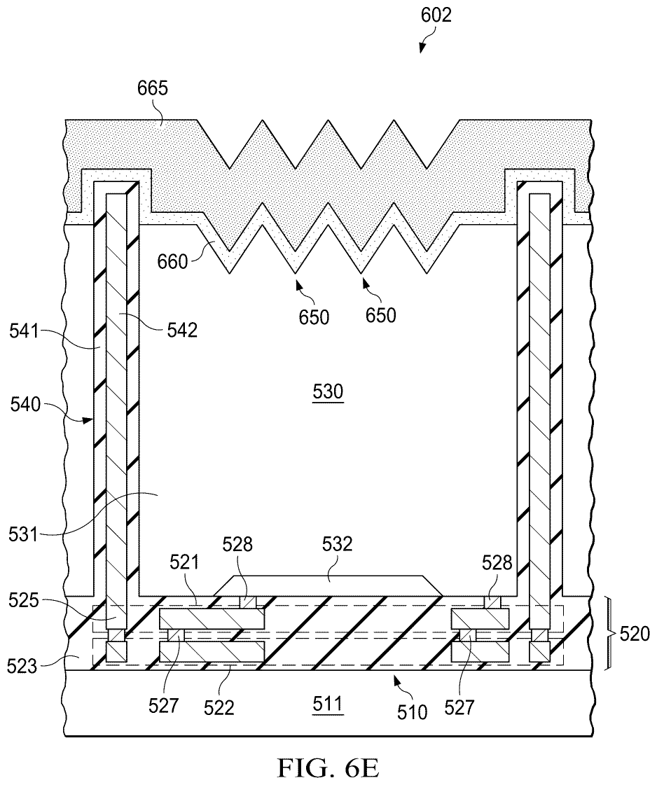

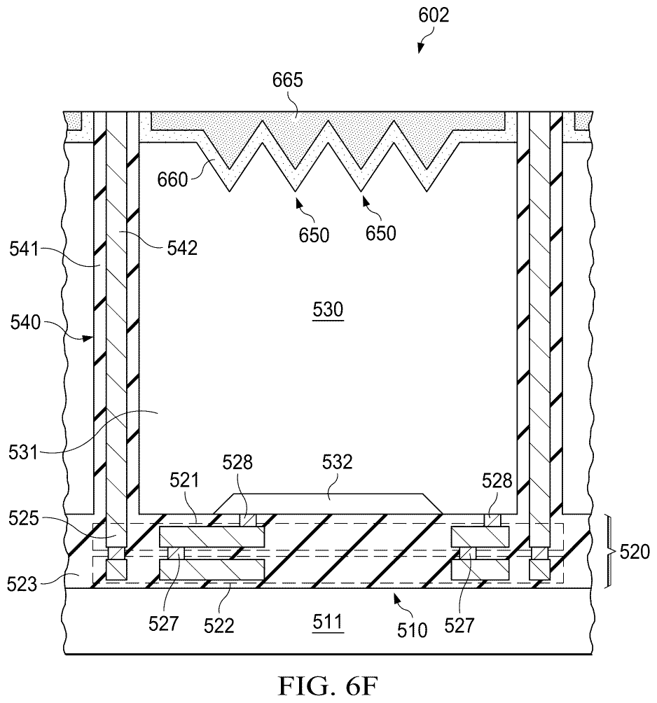

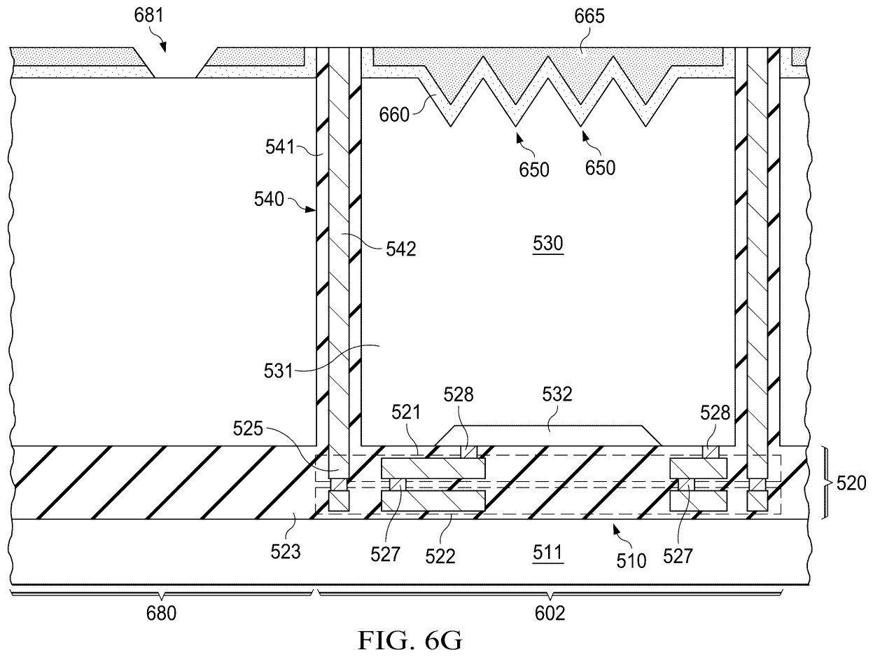

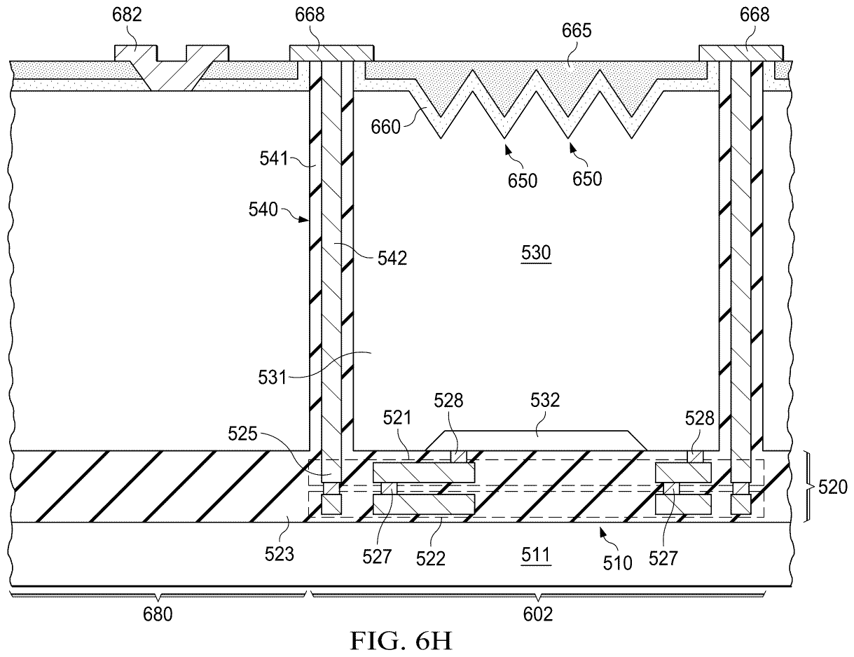

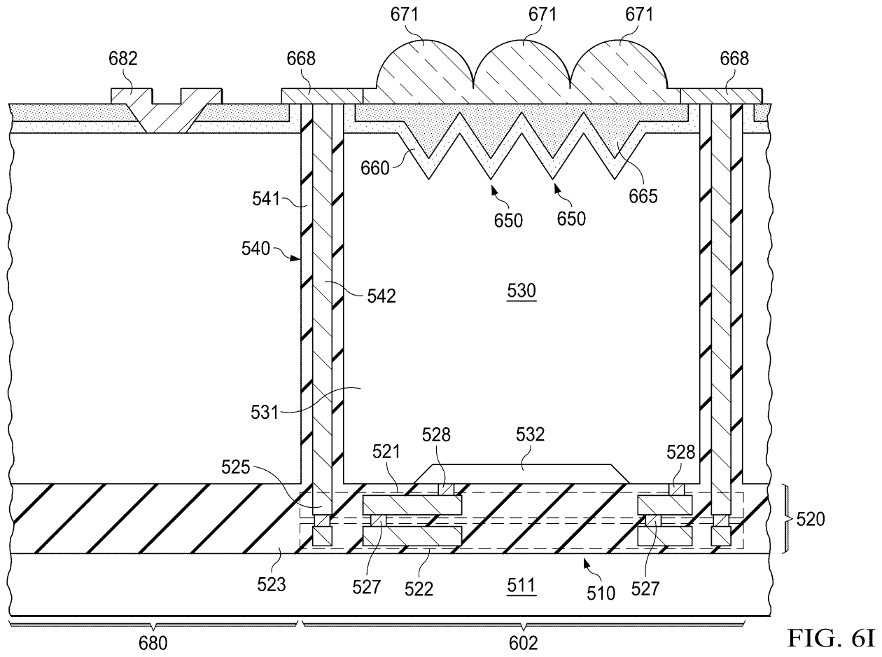

FIGS. 6A-6I illustrate side cross-sectional views of image pixel 602 at different stages of back-side processing utilized to form image pixel 602 in accordance with embodiments of the present disclosure. FIGS. 6G-6I in particular further include a view of a peripheral area to the side of an instance of image pixel 602 on the outside edge of an array of image pixels in accordance with embodiments of the present disclosure.

Image pixel 602 may be a SPAD-based image pixel and may also be referred to as SPAD-based image pixel 602. Although a single instance of image pixel 602 is illustrated in FIGS. 6A-6I, image pixel 602 may be one of a plurality of image pixels in an array. For example, image pixel 602 may represent an embodiment of each of the plurality of SPAD-based image pixels 202 in array 120 of SPAD-based semiconductor device 14 described above with reference to FIG. 3. And in embodiments where SPAD-based semiconductor device 14 is implemented with an array of SiPMs, multiple instances of SPAD-based image pixel 602 may be grouped together to form each SiPM in the array.

Image pixel 602 may be a back-side illuminated image pixel. For example, during manufacture, various semiconductor processing steps may be applied to the front side 510 of semiconductor region 530. N-type doping may be added to form n-type doping region 532 within the p-type epitaxial region 531 of semiconductor region 530, thereby forming the single-photon avalanche diode. Additional processing steps may be applied to the front side 510 of semiconductor region 530 to form front-side dielectric stack 520 and trench 540. Subsequently, front side 510 may be stacked on an additional substrate 511, which may provide structural support and/or may include corresponding control and readout circuitry to which the metal routing in front-side dielectric stack 520 may be coupled. Additional processing may then be applied to the back side of semiconductor region 530 as described below with reference to FIGS. 6A-6I.

As shown in FIG. 6A, the back side may initially include semiconductor substrate 535. Semiconductor substrate 535 may be for example a heavily doped p-type substrate on which the p-type epitaxial region 531 of semiconductor region 530 was previously grown. Various etching and polishing steps may be applied to the back side to remove semiconductor substrate 535 and to etch semiconductor region 530 down to a height lower than the upper end of trench 540, as shown in FIG. 6B. For example, an hydrofluoric-nitric-acetic (HNA) acid etch may be applied to remove semiconductor substrate 535. Such an HNA etch may selectively etch a more heavily doped p-type substrate at a faster rate than a lesser doped p-type epitaxial region, and may thus provide an efficient process for quickly removing semiconductor substrate 535 and stopping the HNA etch at or near the border of semiconductor substrate 535 and p-type epitaxial region 531. A chemical-mechanical planarization (CMP) step may then be applied to smooth the etched surface. Subsequently, an isotropic wet or dry etch may be applied to further etch p-type epitaxial region 531. Such an isotropic wet or dry etch may selectively etch the silicon of p-type epitaxial region 531 while not etching, to a significant degree, the dielectric material of the dielectric wall 541 on the outer edges of trench 540. Thus, as shown in FIG. 6B, semiconductor region 530 may be etched down to a height lower than the upper end of trench 540. In some embodiments, trench 540 may extend from at least the first metal layer 521 disposed in front-side dielectric stack 520 to at least an upper surface of semiconductor region 530. And in some embodiments as shown in FIG. 6B, trench 540 may extend from at least the first metal layer 521 disposed in front-side dielectric stack 520 to above an upper surface of semiconductor region 530.

Moving to FIG. 6C, an oxide layer 651 may be added, by deposition for example, over semiconductor region 530 and the exposed ends of trench 540. Subsequently, a Tetramethylammonium hydroxide (TMAH) etch may be applied to form a plurality of scattering structures 650. In some embodiments, the etch may be applied from certain patterned start points along the upper surface of semiconductor region 530 and follow the crystallographic structure of the silicon forming semiconductor region 530. As shown in FIG. 6D, the plurality of scattering structures 650 may each have a reverse pyramid shape pointing into semiconductor region 530 due to the etching along the crystallographic structure of semiconductor region 530. After the formation of scattering structures 650, oxide layer 651 may be removed, for example, by a further etch process.

Moving to FIG. 6E, passivation layer 660 and buffer layer 665 may be added over semiconductor region 530 and the exposed ends of trench 540. Passivation layer 660 may be located on the upper surface of semiconductor region 530, including on the upper surface of the scattering structures 650 formed at the upper surface of semiconductor region 530. Passivation layer 660 may be formed with a high-k dielectric. For example, passivation layer 660 may include layers of one or more of aluminum oxide, hafnium oxide, and/or tantalum oxide. From an optical standpoint, passivation layer 660 may improve the passage of light into semiconductor region 530. Specifically, passivation layer 660 may provide an intermediate refractive index between buffer layer 665 and semiconductor region 530, thereby improving the passage of light into semiconductor region 530 and reducing the reflection of light at the border of semiconductor region 530.

Buffer layer 665 may be added above passivation layer 660. In some embodiments, buffer layer 665 may be formed with an oxide material such as silicon dioxide. Buffer layer 665 may thus be added above passivation layer 660 by, for example, deposition. As shown in FIG. 6E, buffer layer 665 may have a lower surface that fills in the trenches of the plurality of scattering structures 650.

After adding buffer layer 665, a CMP process may be applied to the upper surface to planarize an upper surface of buffer layer 665 and to expose metal liner 542 at the upper end of trench 540 as shown in FIG. 6F.

Moving to FIG. 6G, further patterning and etching steps may be performed on the front side to provide a peripheral via 681 through the layers of buffer layer 665 and passivation layer 660 in a periphery 680 located to the side of image pixel 602. As described above, periphery 680 may be a periphery area to the side of an instance of image pixel 602 that is located on the edge of an image-pixel array.

Moving to FIG. 6H, metal patterning may be performed on upper surface of image pixel 602 and periphery 680. For example, metal lines may be formed above the exposed upper surface of metal liner 542 to form back-side grid 668. As shown in FIG. 6H, back-side grid 668 may be located above buffer layer 665 and passivation layer 660. In some embodiments, back-side grid 668 may follow the form of trench 540 in a square pattern around each instance of image pixel 602 from a top-side or bottom-side view, thus forming a grid pattern across the top side of an image-pixel array. In some embodiments, back-side grid 668 may come into contact with metal liner 542 of trench 540 and may thus be electrically coupled to metal liner 542 of trench 540. As also shown in FIG. 6H, periphery contact 682 may be formed to fill peripheral via 681. Periphery contact 682 may thus be utilized to make electrical contact with the semiconductor region in periphery 680. For example, although not shown in FIG. 6H, periphery contact 682 may be electrically coupled to the back-side grid 668, and may thus couple the semiconductor region in periphery 680, outside of the pixel array, to back-side grid 668.

Moving to FIG. 6I, a lens layer may be added. As shown in FIG. 6I for example, lens layer 670 may be located above buffer layer 665 and passivation layer 660, and may be configured to focus light into semiconductor region 530. In some embodiments, lens layer 670 may include at least one microlens 671 configured to focus light into semiconductor region 530. Microlenses 671 may be formed with either an organic or an inorganic material. For example, microlenses 671 may in some embodiments be formed with an inorganic oxide material. In other embodiments, microlenses 671 may be formed with an organic material, such as an acrylic-based polymer. The upper surface of each microlens 671 may have a spherical convex shape. Microlenses 671 may thus refract the light received by image pixel 602 and focus that light into the semiconductor region 530 of image pixel 602.

As shown in FIG. 6I, trench 540 may extend above an upper surface of semiconductor region 530. Trench 540, and in particular metal liner 542, may be coupled to back-side grid 668. Back-side grid 668 may be located above the upper surface of semiconductor region 530, passivation layer 660, and buffer layer 665. As described above, metal liner 542 may comprise at least one of tungsten and copper. Metal liner 542 may thus block secondary photons generated in semiconductor region 530 from reflecting off the upper surface of semiconductor region 530, or off of passivation layer 660 or buffer layer 665, and into a neighboring image pixel. As also shown in FIG. 6I, lens layer 670 may be located at least in part at a level even with or below a level of back-side grid 668. For example, as shown in FIG. 6I, portions of lens layer 670 may be located below an upper surface of back-side grid 668. And as described above, back-side grid 668 may comprise an absorptive metal, such as tungsten. Accordingly, back-side grid 668 may block secondary photons generated in semiconductor region 530 from reflecting off lens layer 670 and into a neighboring image pixel.

The amount of cross-talk induced by secondary photons generated in semiconductor region 530 may thus be reduced by the presence of trench 540 extending at least to the upper surface of semiconductor region 530, and in some embodiments beyond the upper surface of semiconductor region 530, as well as by the coupling of the metal liner 542 of trench 540 to back-side grid 668. Moreover, such improved crosstalk may be achieved according to the embodiments disclosed herein without causing metal contamination within semiconductor region 530. For example, during back-side processing of image pixel 602, any exposure of semiconductor region 530 to metals, such as copper or tungsten, may cause unwanted metal contamination that may result in increased dark currents in the SPAD-based image pixel. But as described above and shown in FIGS. 6A-6I, the back-side processing of image pixel 602 may be performed without exposing semiconductor region 530 to unwanted metal contamination. For example, as shown in FIG. 6B, when etching semiconductor region 530 down to a height lower than the upper end of trench 540, metal liner 542 within trench 540 may remain enclosed within dielectric wall 541. Thus, unwanted metal contamination from metal liner 542 to the exposed semiconductor region 530 may be reduced or prevented. Further, as shown in FIGS. 6F-6H, semiconductor region 530 may be shielded by passivation layer 660 and buffer layer 665 during processing steps when metal liner 542 is exposed (FIG. 6F), or when further metallization is being added to the back side of image pixel 602 (FIGS. 6G-6H). Accordingly, the advantages of reduced crosstalk may be realized by image pixel 602 without incurring unwanted metal exposure during back-side processing.

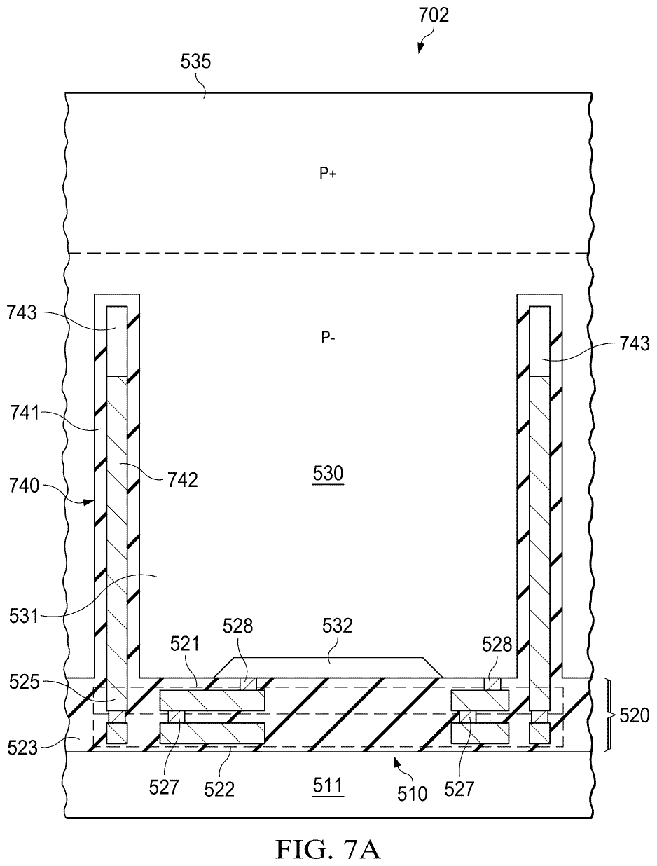

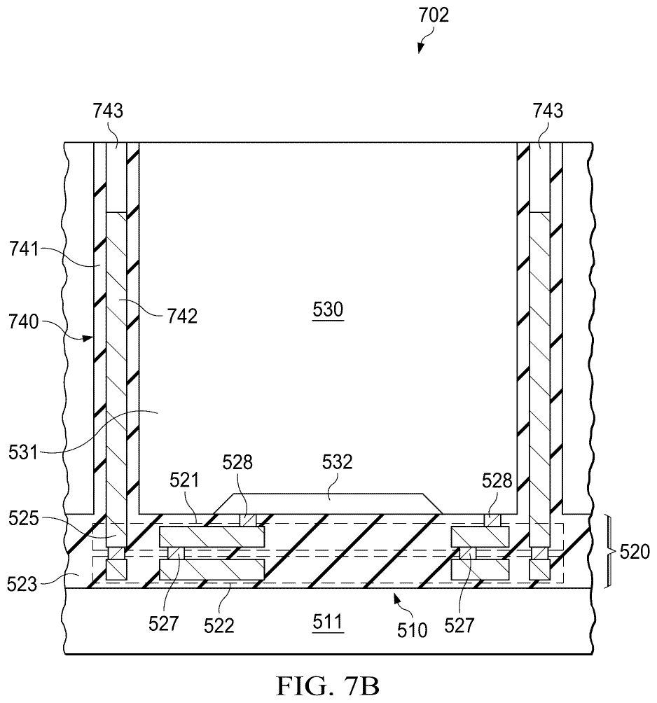

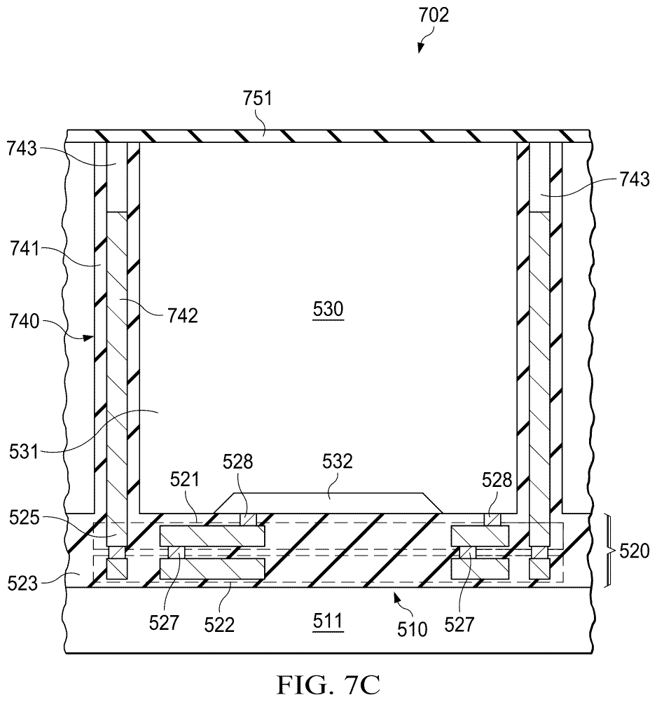

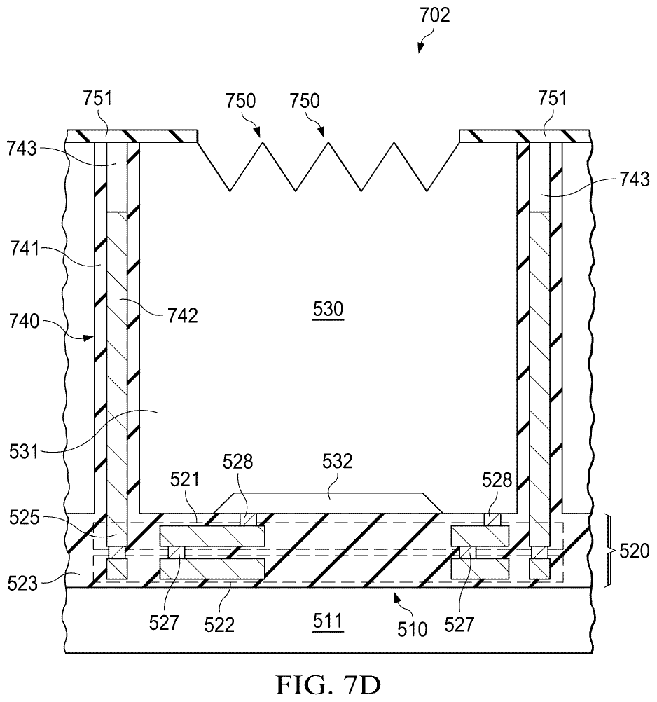

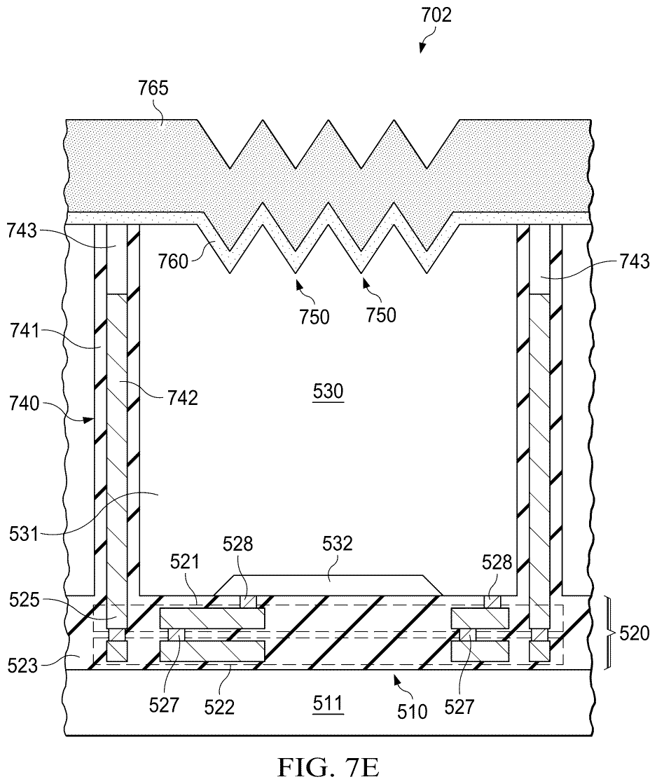

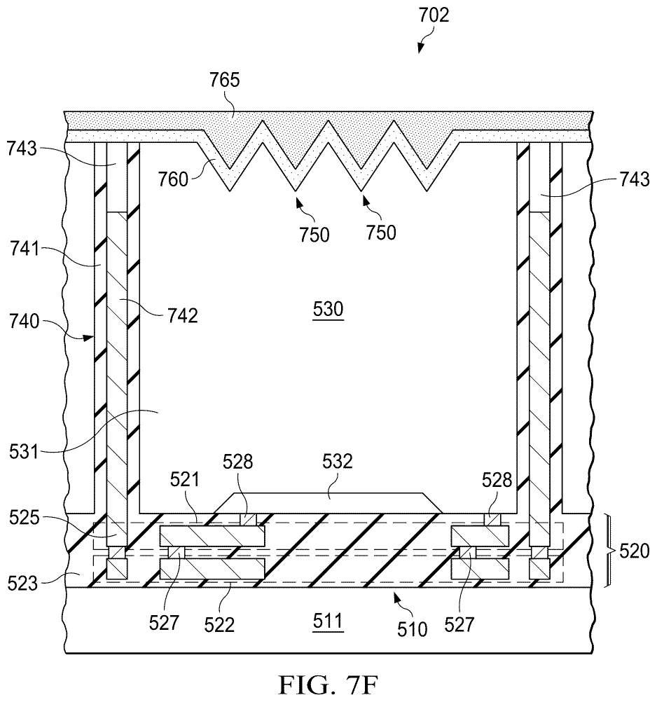

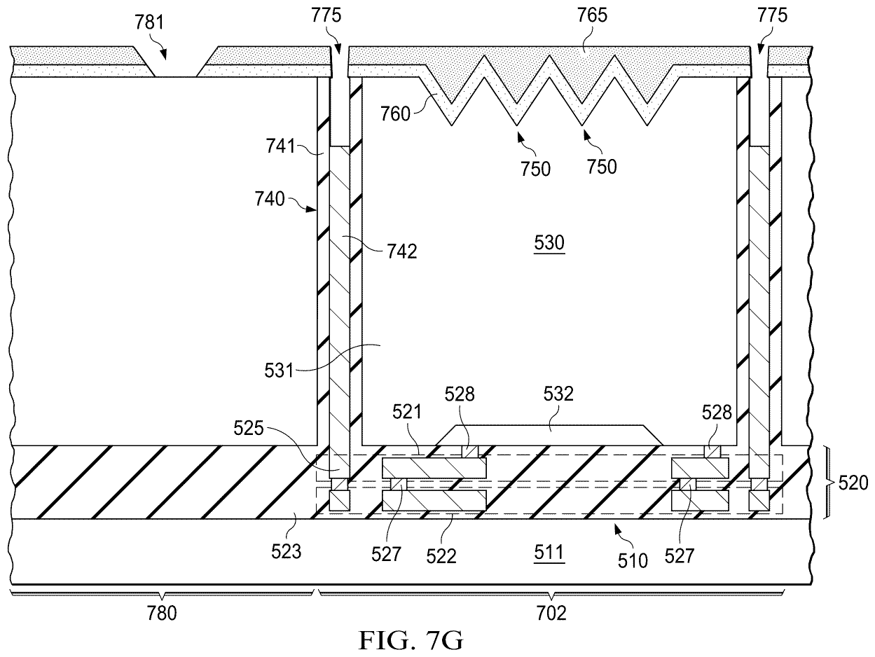

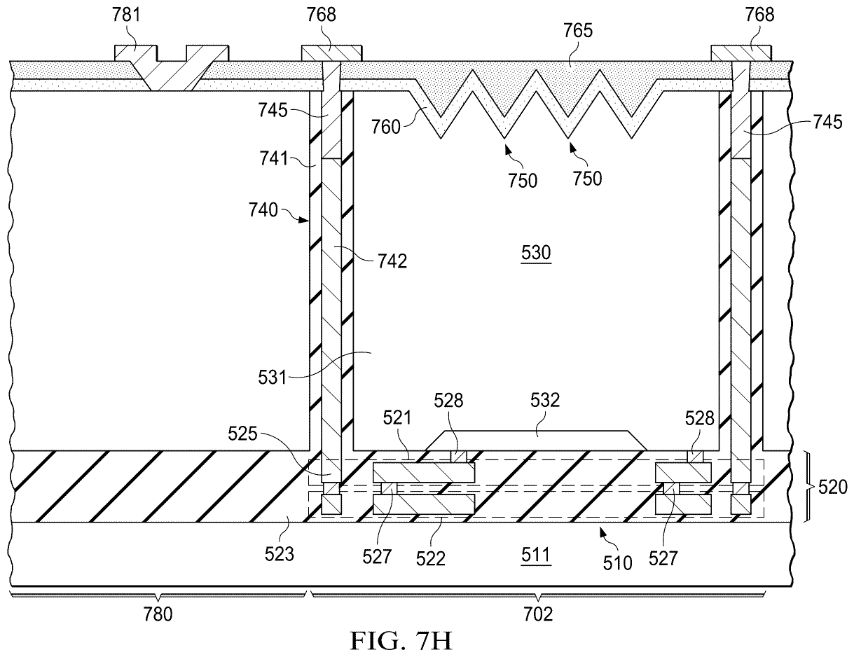

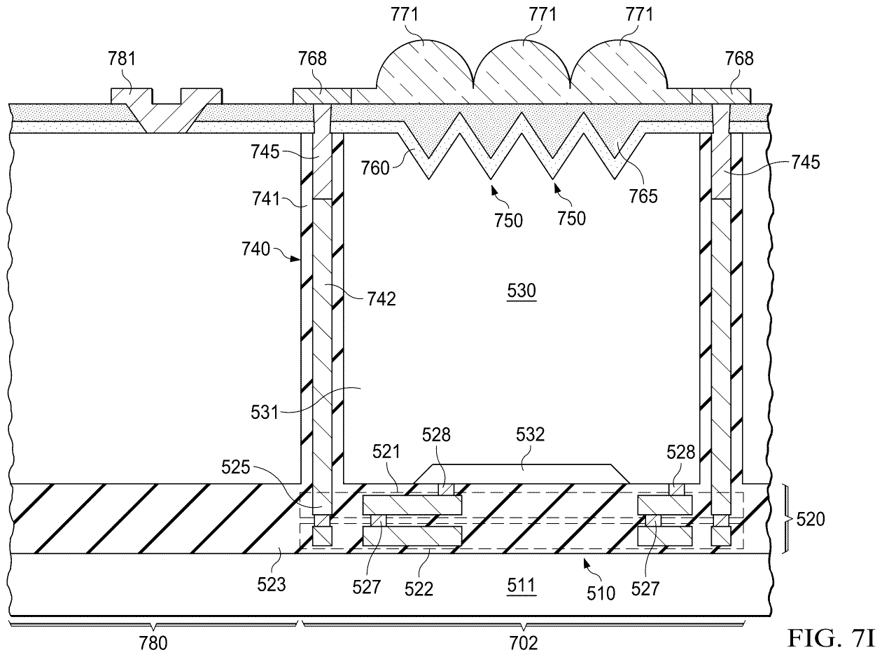

FIGS. 7A-7I illustrate side cross-sectional views of image pixel 702 at different stages of back-side processing utilized to form image pixel 702 in accordance with embodiments of the present disclosure. FIGS. 7G-7I in particular further include a view of a peripheral area to the side of an instance of image pixel 702 on the outside edge of an array of image pixels in accordance with embodiments of the present disclosure.

Image pixel 702 may be a SPAD-based image pixel and may also be referred to as SPAD-based image pixel 702. Although a single instance of image pixel 702 is illustrated in FIGS. 7A-7I, image pixel 702 may be one of a plurality of image pixels in an array. For example, image pixel 702 may represent an embodiment of each of the plurality of SPAD-based image pixels 202 in array 120 of SPAD-based semiconductor device 14 described above with reference to FIG. 3. And in embodiments where SPAD-based semiconductor device 14 is implemented with an array of SiPMs, multiple instances of SPAD-based image pixel 702 may be grouped together to form each SiPM in the array.

Image pixel 702 may be a back-side illuminated image pixel. For example, during manufacture, various semiconductor processing steps may be applied to the front side 510 of semiconductor region 530. N-type doping may be added to form n-type doping region 532 within the p-type epitaxial region 531 of semiconductor region 530, thereby forming the single-photon avalanche diode. Additional processing steps may be applied to the front side 510 of semiconductor region 530 to form front-side dielectric stack 520 and trench 740. Subsequently, front side 510 may be stacked on an additional substrate 511, which may provide structural support and/or may include corresponding control and readout circuitry to which the metal routing in front-side dielectric stack 520 may be coupled. Additional processing may then be applied to the back side of semiconductor region 530 as described below with reference to FIGS. 7A-7I.

As shown in FIG. 7A, image pixel 702 may include trench 740. During manufacture of image pixel 702, trench 740 may be formed, for example, by an etch and fill process from the front side 510 prior to the formation of front-side dielectric stack 520. Trench 740 may include dielectric wall 741, a metal liner 742 interior to dielectric wall 741, and a polysilicon filler 743 interior to dielectric wall 741 at an upper end of trench 740. For example, after an etch process, a dielectric material may be deposited to form dielectric wall 741 along the edges of the etched area. A polysilicon material may then be deposited to form polysilicon filler 743 at the end of trench 740. Subsequently, a metal material may be deposited in the remainder of the etched area to form metal liner 742 interior to dielectric wall 741. The dielectric material forming dielectric wall 741 may include, for example, silicon dioxide. Dielectric wall 741 may thus electrically isolate one instance of image pixel 702 from neighboring instances of image pixel 702 in an array. In some embodiments, metal liner 742 may be formed with a reflective metal such as copper. In other embodiments, metal liner 742 may be formed with an absorptive metal such as tungsten. Whether by reflection or absorption, metal liner 742 may prevent photons of light from passing through one instance of image pixel 702 to a neighboring instance of image pixel 702, thereby reducing or eliminating unwanted optical crosstalk between neighboring instances of image pixel 702. Specifically, metal liner 742 of trench 740 may prevent secondary photons generated during the avalanche from passing into a neighboring image pixel and causing optical crosstalk.

As shown in FIG. 7A, the back side may initially include semiconductor substrate 535. Various etching and polishing steps, similar to those described above with reference to FIG. 6A, may be applied to the back side to remove semiconductor substrate 535. Further, as shown in FIG. 7B, semiconductor region 530 and/or trench 740 may be etched and/or polished to a level where the upper surface of semiconductor region 530 is even with exposed polysilicon filler 743 of trench 740.

Moving to FIG. 7C, an oxide layer 751 may be added, by deposition for example, over semiconductor region 530 and the exposed ends of trench 740. Subsequently, a TMAH etch may be applied to form a plurality of scattering structures 750 in a similar manner as described above with reference to FIGS. 6C and 6D. Thus, as shown in FIG. 7D, the plurality of scattering structures 750 may each have a reverse pyramid shape pointing into semiconductor region 530 due to the etching along the crystallographic structure of semiconductor region 530. After the formation of scattering structures 750, oxide layer 751 may be removed, for example, by a further etch process.

Moving to FIG. 7E, passivation layer 760 and buffer layer 765 may be added over semiconductor region 530 and the exposed ends of trench 740. Passivation layer 760 may be formed with a high-k dielectric. For example, passivation layer 760 may include layers of one or more of aluminum oxide, hafnium oxide, and/or tantalum oxide. From an optical standpoint, passivation layer 760 may improve the passage of light into semiconductor region 530. Specifically, passivation layer 760 may provide an intermediate refractive index between buffer layer 765 and semiconductor region 530, thereby improving the passage of light into semiconductor region 530 and reducing the reflection of light at the border of semiconductor region 530.

Buffer layer 765 may be added above passivation layer 760. In some embodiments, buffer layer 765 may be formed with an oxide material such as silicon dioxide. Buffer layer 765 may thus be added above passivation layer 760 by, for example, deposition. As shown in FIG. 7E, buffer layer 765 may have a lower surface that fills in the trenches of the plurality of scattering structures 750. After adding buffer layer 765, a CMP process may be applied to the upper surface to planarize an upper surface of buffer layer 765 as shown in FIG. 7F.

Moving to FIG. 7G, further patterning and etching steps may be performed on the front side. For example, an etch may be applied to form a hole 775 through passivation layer 760 and buffer layer 765 above trench 740, as well as to provide a peripheral via 781 through the layers of buffer layer 765 and passivation layer 760 in a periphery 780 located to the side of image pixel 702. As described above, periphery 780 may be a periphery area to the side of an instance of image pixel 702 that is located on the edge of an image-pixel array. Further polysilicon-specific etching may then be applied to remove polysilicon filler 743.

Moving to FIG. 7H, a metal material may be deposited into hole 775 to form metal filler 745. As shown in FIG. 7H, metal filler 745 may occupy the space within trench 740 vacated by polysilicon filler 743. Metal filler 745 may also fill the space of hole 775 to form a metal contact from the metal portions of trench 740 to upper surface of buffer layer 765. In some embodiments, metal filler 745 may be comprised of the same type of metal material as metal liner 742. For example, metal filler 745 may comprise at least one of tungsten and copper. Further metal patterning may be performed on upper surface of image pixel 702 and periphery 780. For example, metal lines may be formed above the exposed upper surface of metal filler 745 to form back-side grid 768. As shown in FIG. 7H, back-side grid 768 may be located above buffer layer 765 and passivation layer 760. In some embodiments, back-side grid 768 may follow the form of trench 740 in a square pattern around each instance of image pixel 702 from a top-side or bottom-side view perspective, thus forming a grid pattern across the top side of an image-pixel array. In some embodiments, back-side grid 768 may be placed over and in contact with metal filler 745. Back-side grid 768 may thus be electrically coupled to metal liner 742 of trench 740. As also shown in FIG. 7H, periphery contact 782 may be formed to fill peripheral via 781. Periphery contact 782 may thus be utilized to make electrical contact with the semiconductor region in periphery 780. For example, although not shown in FIG. 7H, periphery contact 782 may be electrically coupled to the back-side grid 768, and may thus couple the semiconductor region in periphery 780, outside of the pixel array, to back-side grid 768.

Moving to FIG. 7I, a lens layer may be added. As shown in FIG. 7I for example, lens layer 770 may be located above buffer layer 765 and passivation layer 760, and may be configured to focus light into semiconductor region 530. In some embodiments, lens layer 770 may include at least one microlens 771 configured to focus light into semiconductor region 530. Microlenses 771 may be formed with either an organic or an inorganic material. For example, microlenses 771 may in some embodiments be formed with an inorganic oxide material. In other embodiments, microlenses 771 may be formed with an organic material, such as an acrylic-based polymer. The upper surface of each microlens 771 may have a spherical convex shape. Microlenses 771 may thus refract the light received by image pixel 702 and focus that light into the semiconductor region 530 of image pixel 702.

As shown in FIG. 7I, trench 740 may extend from at least a first metal layer 521 disposed in front-side dielectric stack 520 to an upper surface of semiconductor region 530. Trench 740, and in particular metal liner 742, may be coupled to back-side grid 768 through metal filler 745. Back-side grid 768 may be located above the upper surface of semiconductor region 530, passivation layer 760, and buffer layer 765. As described above, metal liner 742 and metal filler 745 may comprise at least one of tungsten and copper. Metal liner 742 and metal filler 745 may thus block secondary photons generated in semiconductor region 530 from reflecting off the upper surface of semiconductor region 530, or off of passivation layer 760 or buffer layer 765, and into a neighboring image pixel. As also shown in FIG. 7I, lens layer 770 may be located at least in part at a level even with or below a level of back-side grid 768. For example, as shown in FIG. 7I, portions of lens layer 770 may be located below an upper surface of back-side grid 768. And as described above, back-side grid 768 may comprise an absorptive metal, such as tungsten. Accordingly, back-side grid 768 may block secondary photons generated in semiconductor region 530 from reflecting off lens layer 770 and into a neighboring image pixel. The configuration of trench 740, metal filler 745, and back-side grid 768 may thus reduce the amount of cross-talk between neighboring instances of image pixel 702 induced by secondary photons generated in semiconductor region 530.

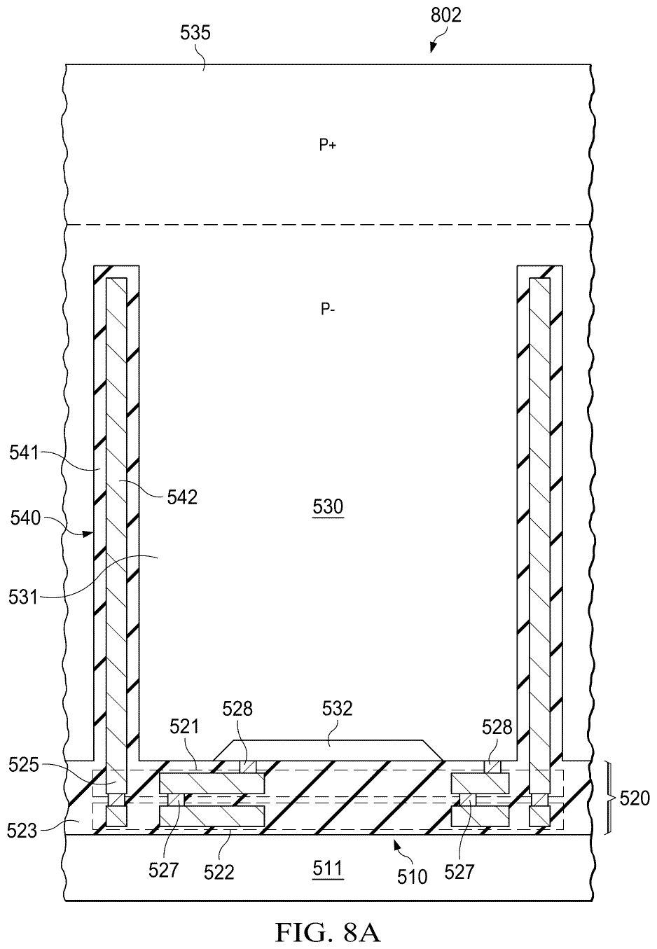

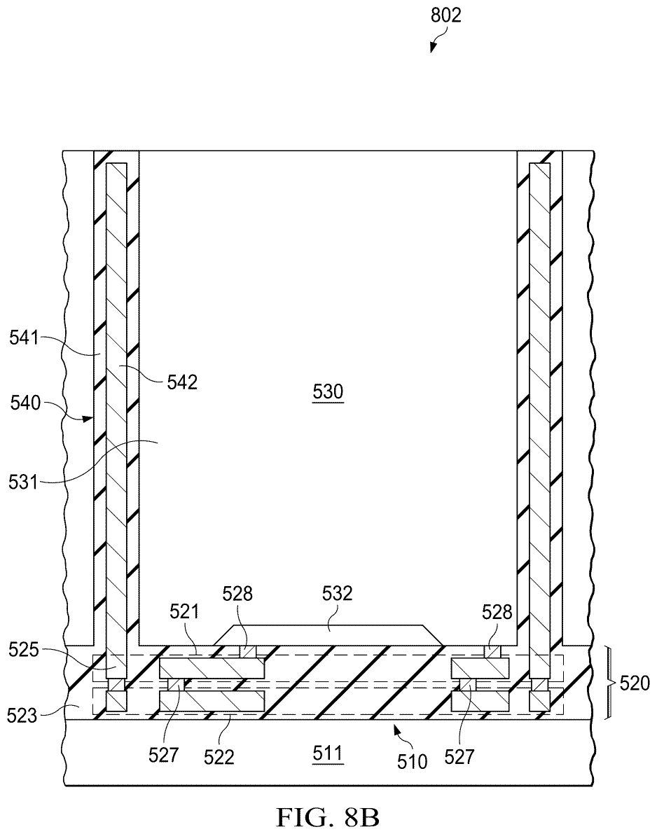

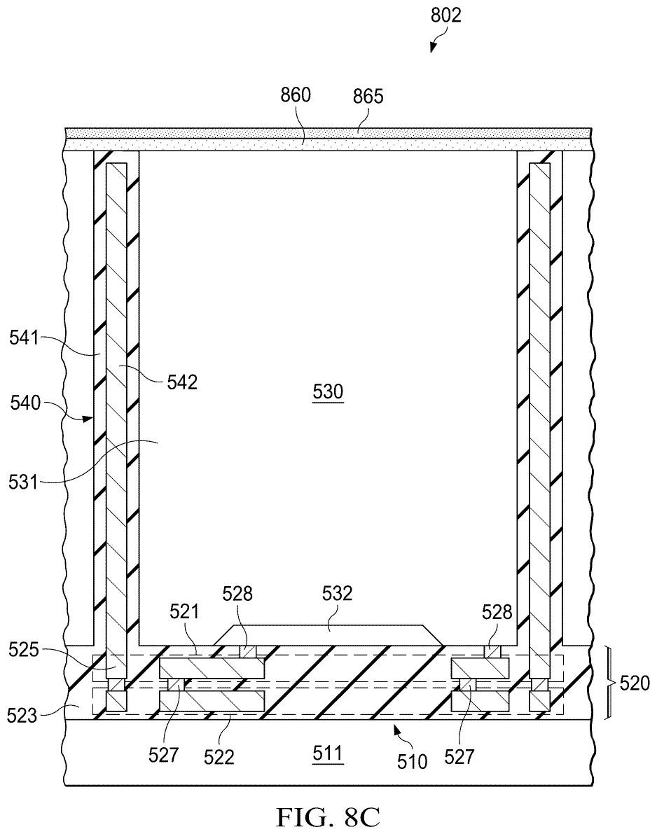

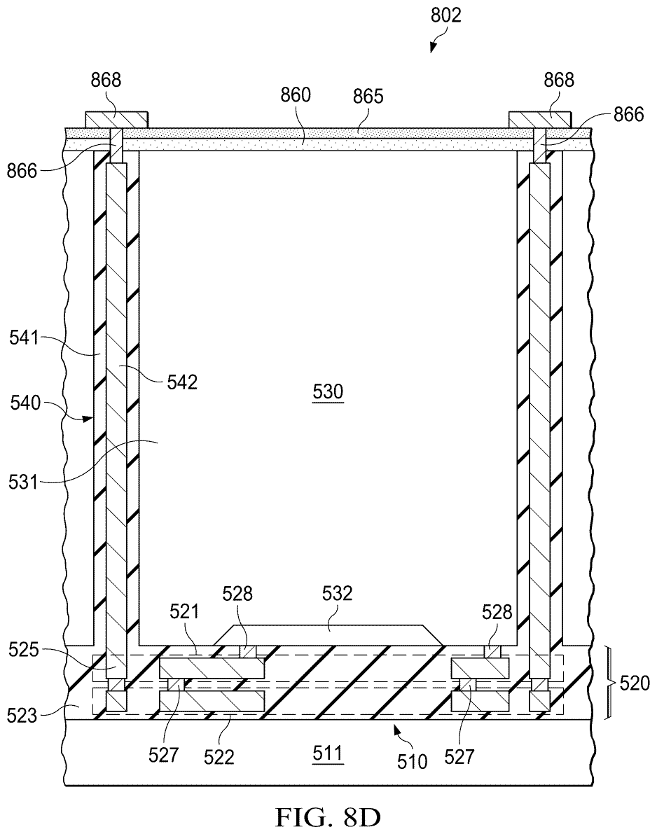

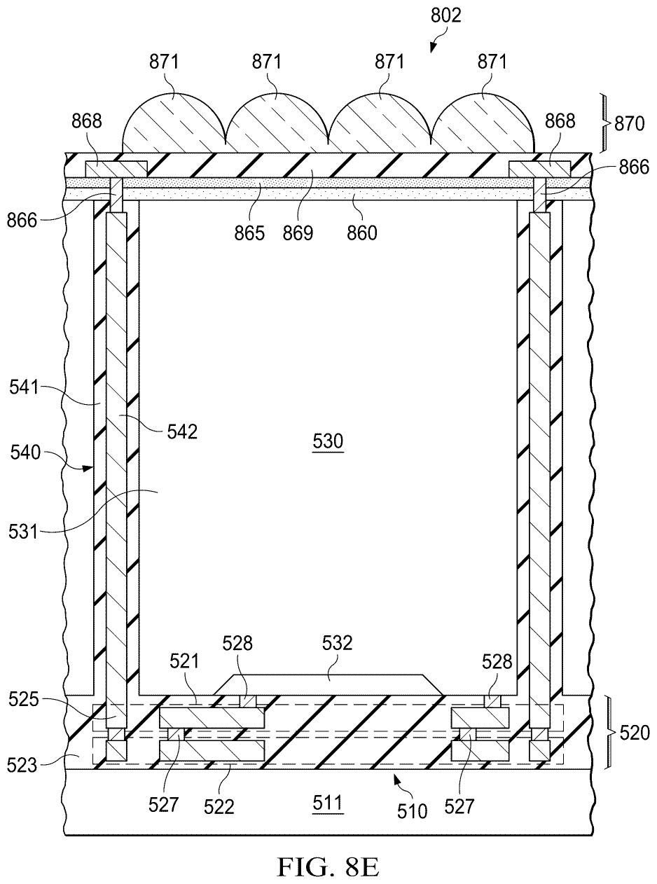

FIGS. 8A-8E illustrate side cross-sectional views of image pixel 802 at different stages of back-side processing utilized to form image pixel 802 in accordance with embodiments of the present disclosure.

Image pixel 802 may be a SPAD-based image pixel and may also be referred to as SPAD-based image pixel 802. Although a single instance of image pixel 802 is illustrated in FIGS. 8A-8E, image pixel 802 may be one of a plurality of image pixels in an array. For example, image pixel 802 may represent an embodiment of each of the plurality of SPAD-based image pixels 202 in array 120 of SPAD-based semiconductor device 14 described above with reference to FIG. 3. And in embodiments where SPAD-based semiconductor device 14 is implemented with an array of SiPMs, multiple instances of SPAD-based image pixel 802 may be grouped together to form each SiPM in the array.

Image pixel 802 may be a back-side illuminated image pixel. For example, during manufacture, various semiconductor processing steps may be applied to the front side 510 of semiconductor region 530. N-type doping may be added to form n-type doping region 532 within the p-type epitaxial region 531 of semiconductor region 530, thereby forming the single-photon avalanche diode. Additional processing steps may be applied to the front side 510 of semiconductor region 530 to form front-side dielectric stack 520 and trench 540. Subsequently, front side 510 may be stacked on an additional substrate 511, which may provide structural support and/or may include corresponding control and readout circuitry to which the metal routing in front-side dielectric stack 520 may be coupled. Additional processing may then be applied to the back side of semiconductor region 530 as described below with reference to FIGS. 8A-8E.

As shown in FIG. 8A, the back side may initially include semiconductor substrate 535. Various etching and polishing steps, similar to those described above with reference to FIG. 6A, may be applied to the back side to remove semiconductor substrate 535. Further, as shown in FIG. 8B, semiconductor region 530 may be etched and/or polished to a level where the upper surface of semiconductor region 530 is even with an upper end of trench 540.

Moving to FIG. 8C, passivation layer 860 and buffer layer 865 may be added over semiconductor region 530 and trench 540. Passivation layer 860 may be formed with a high-k dielectric. For example, passivation layer 860 may include layers of one or more of aluminum oxide, hafnium oxide, and/or tantalum oxide. From an optical standpoint, passivation layer 860 may improve the passage of light into semiconductor region 530. Specifically, passivation layer 860 may provide an intermediate refractive index between buffer layer 865 and semiconductor region 530, thereby improving the passage of light into semiconductor region 530 and reducing the reflection of light at the border of semiconductor region 530. In some embodiments, buffer layer 865 may be formed with an oxide material such as silicon dioxide. Buffer layer 865 may thus be added above passivation layer 860 by, for example, deposition.

Moving to FIG. 8D, metal contact 866 and back-side grid 868 may be added to the back side of image pixel 802. In some embodiments, a hole may be etched through buffer layer 865, passivation layer 860, and dielectric wall 541 of trench 540. The hole may then be filled with a metal material to form metal contact 866. In some embodiments, metal contact 866 may be comprised of the same type of metal material as metal liner 542. For example, metal contact 866 may comprise at least one of tungsten and copper. As shown in FIG. 8D, further metal patterning may be performed on upper surface of image pixel 802. For example, metal lines may be formed above the metal contacts 866 to form back-side grid 868. As shown in FIG. 8D, back-side grid 868 may be located above buffer layer 865 and passivation layer 860. In some embodiments, back-side grid 868 may follow the form of trench 540 in a square pattern around each instance of image pixel 802 from a top-side or bottom-side view perspective, thus forming a grid pattern across the top side of an image-pixel array. In some embodiments, back-side grid 868 may be placed over and in contact with metal contact 866. Back-side grid 868 may thus be electrically coupled to metal liner 542 of trench 540. In some embodiments, metal liner 542 may in turn be coupled to ground through metal routing in first metal layer 521 and/or second metal layer 522 of front-side dielectric stack 520.

Moving to FIG. 8E, an oxide layer 869 may be added above buffer layer 865 and passivation layer 860, and above back-side grid 868. In some embodiments, oxide layer 869 may comprise silicon dioxide. The upper surface of oxide layer 869 may be planarized, and lens layer 870 may be formed on the upper surface of oxide layer 869.

As shown in FIG. 8E for example, lens layer 870 may be located above passivation layer 860, buffer layer 865, and oxide layer 869, and may be configured to focus light into semiconductor region 530. In some embodiments, lens layer 870 may include at least one microlens 871 configured to focus light into semiconductor region 530. Microlenses 871 may be formed with either an organic or an inorganic material. For example, microlenses 871 may in some embodiments be formed with an inorganic oxide material. In other embodiments, microlenses 871 may be formed with an organic material, such as an acrylic-based polymer. The upper surface of each microlens 871 may have a spherical convex shape. Microlenses 871 may thus refract the light received by image pixel 802 and focus that light into the semiconductor region 530 of image pixel 802.

As shown in FIG. 8E, and as implemented in image pixel 802, trench 540 may extend from the first metal layer 521 disposed in front-side dielectric stack 520 to a top surface of semiconductor region 530. Further, image pixel 802 may include metal contact 866 extending from back-side grid 868 to metal liner 542 of trench 540. As described above, metal liner 542 and metal contact 866 may comprise at least one of tungsten and copper. Metal liner 542 and metal contact 866 may thus block secondary photons generated in semiconductor region 530 from reflecting off the upper surface of semiconductor region 530, passivation layer 860, or buffer layer 865, and into a neighboring image pixel. The configuration of trench 540, metal contact 866, and back-side grid 868 may thus reduce the amount of cross-talk between neighboring instances of image pixel 802 induced by secondary photons generated in semiconductor region 530.

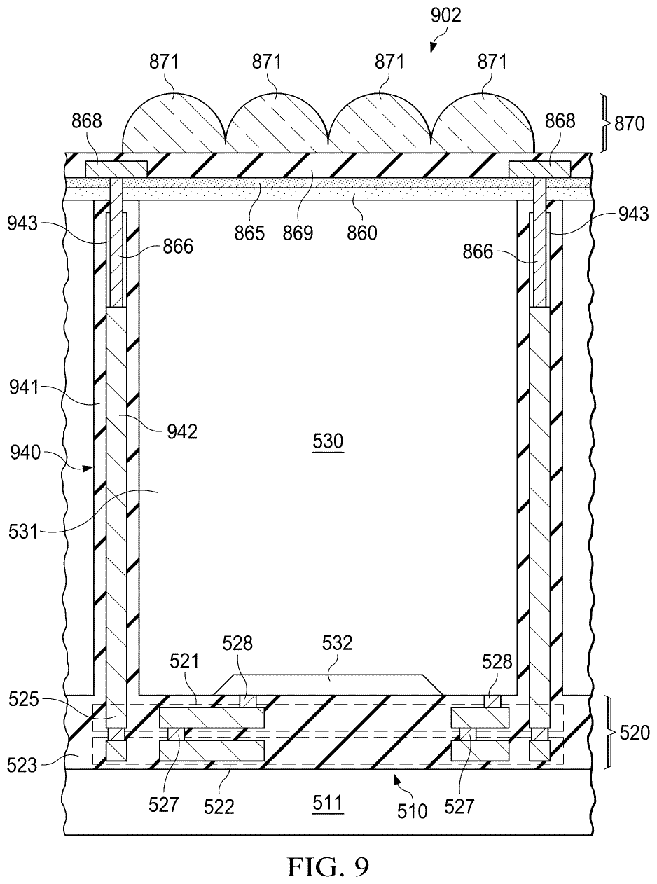

FIG. 9 illustrates a side cross-sectional view of image pixel 902 in accordance with embodiments of the present disclosure. Image pixel 902 may be a SPAD-based image pixel and may also be referred to as SPAD-based image pixel 902. Although a single instance of image pixel 902 is illustrated in FIG. 9, image pixel 902 may be one of a plurality of image pixels in an array. For example, image pixel 902 may represent an embodiment of each of the plurality of SPAD-based image pixels 202 in array 120 of SPAD-based semiconductor device 14 described above with reference to FIG. 3. And in embodiments where SPAD-based semiconductor device 14 is implemented with an array of SiPMs, multiple instances of SPAD-based image pixel 902 may be grouped together to form each SiPM in the array.

Image pixel 902 may be formed in a similar manner as image pixel 802 described above with reference to FIGS. 8A-8E, but with certain features as described directly below. For example, image pixel 902 may include trench 940. Similar to trench 540, trench 940 may extend from the first metal layer 521 disposed in front-side dielectric stack 520 to a top surface of semiconductor region 530. To improve manufacturability, the upper end of trench 940 may include a polysilicon liner 943. For example, trench 940 may be formed by an etch and fill process from the front side 510 prior to the formation of front-side dielectric stack 520. Trench 940 may include dielectric wall 941, a metal liner 942 interior to dielectric wall 941, and a polysilicon liner 943 interior to dielectric wall 941 at an upper end of trench 740. For example, after an etch process, a dielectric material may be deposited to form dielectric wall 941 along the edges of the etched area. A polysilicon material may then be deposited to form polysilicon liner 943 at the end of trench 940. Subsequently, a metal material may be deposited in the remainder of the etched area to form metal liner 942 interior to dielectric wall 941. The dielectric material forming dielectric wall 941 may include, for example, silicon dioxide. Dielectric wall 941 may thus electrically isolate one instance of image pixel 902 from neighboring instances of image pixel 902 in an array. In some embodiments, metal liner 942 may be formed with a reflective metal such as copper. In other embodiments, metal liner 942 may be formed with an absorptive metal such as tungsten. Whether by reflection or absorption, metal liner 942 may prevent photons of light from passing through one instance of image pixel 902 to a neighboring instance of image pixel 902, thereby reducing or eliminating unwanted optical crosstalk between neighboring instances of image pixel 902.

During the back-side processing, metal contact 866 may be formed such that metal contact 866 extends through polysilicon liner 943 to metal liner 942 of trench 940. Specifically, metal contact 866 may extend from back-side grid 868, through buffer layer 865, passivation layer 860, and the polysilicon liner 943, to metal liner 942 of trench 940. As described above, metal liner 542 and metal contact 866 may comprise at least one of tungsten and copper. Metal liner 542 and metal contact 866 may thus block secondary photons generated in semiconductor region 530 from reflecting off the upper surface of semiconductor region 530, passivation layer 860, or buffer layer 865, and into a neighboring image pixel. The configuration of trench 940, metal contact 866, and back-side grid 868 may thus reduce the amount of cross-talk between neighboring instances of image pixel 902 induced by secondary photons generated in semiconductor region 530.

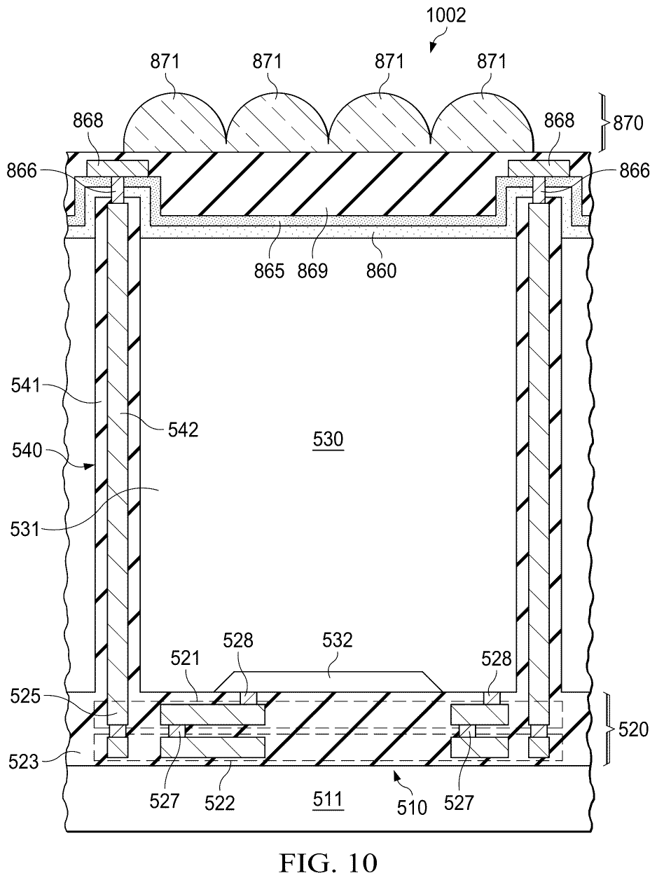

FIG. 10 illustrates a side cross-sectional view of image pixel 1002 in accordance with embodiments of the present disclosure. Image pixel 1002 may be a SPAD-based image pixel and may also be referred to as SPAD-based image pixel 1002. Although a single instance of image pixel 1002 is illustrated in FIG. 10, image pixel 1002 may be one of a plurality of image pixels in an array. For example, image pixel 1002 may represent an embodiment of each of the plurality of SPAD-based image pixels 202 in array 120 of SPAD-based semiconductor device 14 described above with reference to FIG. 3. And in embodiments where SPAD-based semiconductor device 14 is implemented with an array of SiPMs, multiple instances of SPAD-based image pixel 1002 may be grouped together to form each SiPM in the array.

Image pixel 1002 may be formed in a similar manner as image pixel 802 described above with reference to FIGS. 8A-8E, but with certain features as described directly below. For example, as shown in FIG. 10, semiconductor region 530 may be etched down to a level such that trench 540 extends above the upper surface of semiconductor region 530. When oxide layer 869 is later added in subsequent processing steps, oxide layer may thus fill in the recess between opposing ends of trench 540 on the back side of image pixel 1002. The resulting height of the upper end of metal liner 542, metal contact 866, and back-side grid 868, relative to semiconductor region 530 may thus further aid the blocking of secondary photons generated in semiconductor region 530 from reflecting off the upper surface of semiconductor region 530, passivation layer 860, or buffer layer 865, and into a neighboring image pixel.

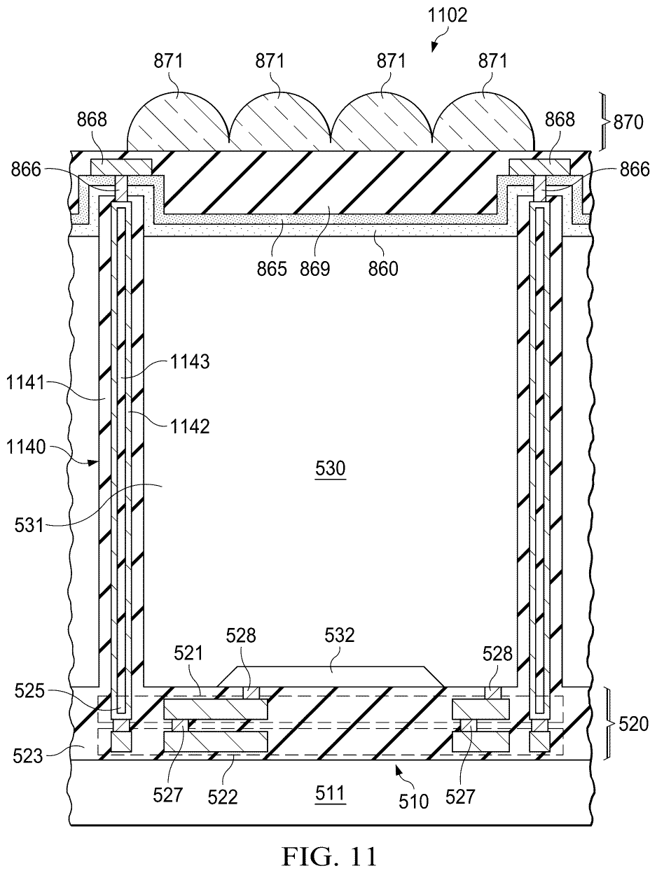

FIG. 11 illustrates a side cross-sectional view of image pixel 1102 in accordance with embodiments of the present disclosure. Image pixel 1102 may be a SPAD-based image pixel and may also be referred to as SPAD-based image pixel 1102. Although a single instance of image pixel 1102 is illustrated in FIG. 11, image pixel 1102 may be one of a plurality of image pixels in an array. For example, image pixel 1102 may represent an embodiment of each of the plurality of SPAD-based image pixels 202 in array 120 of SPAD-based semiconductor device 14 described above with reference to FIG. 3. And in embodiments where SPAD-based semiconductor device 14 is implemented with an array of SiPMs, multiple instances of SPAD-based image pixel 1102 may be grouped together to form each SiPM in the array.

Image pixel 1102 may be formed in a similar manner as image pixel 1002 described above with reference to FIG. 10, but with certain features as described directly below. For example, as shown in FIG. 11, image pixel 1102 may include trench 1140. To improve manufacturability, trench 1140 may include a dielectric liner 1143 surrounded by metal liner 1142. For example, trench 1140 may be formed by an etch and fill process from the front side 510 prior to the formation of front-side dielectric stack 520. Trench 1140 may include dielectric wall 1141, a metal liner 1142 interior to dielectric wall 941, and a dielectric liner 1143 interior to metal liner 1142. For example, after an etch process, a dielectric material such as silicon dioxide may be deposited to form dielectric wall 1141 along the edges of the etched area. A metal material may be deposited to form metal liner 1142 interior to dielectric wall 1141. Further dielectric material, such as further silicon dioxide, may then be deposited in the remainder of the etched area to form dielectric liner 1143 interior to metal liner 1142. Dielectric liner 1143 may thus provide structural support for metal liner 1142 and reduce the amount of metal that is required to form metal liner 1142 relative to embodiments where the metal liner fills the entire interior of dielectric wall 1141.

Dielectric wall 1141 may electrically isolate one instance of image pixel 1102 from neighboring instances of image pixel 1102 in an array. In some embodiments, metal liner 1142 may be formed with a reflective metal such as copper. In other embodiments, metal liner 1142 may be formed with an absorptive metal such as tungsten. Whether by reflection or absorption, metal liner 1142 may prevent photons of light from passing through one instance of image pixel 1102 to a neighboring instance of image pixel 1102, thereby reducing or eliminating unwanted optical crosstalk between neighboring instances of image pixel 1102.

Although dielectric liner 1143 is described above with reference to the example embodiment of image pixel 1102 shown in FIG. 11, such a dielectric liner may also be utilized within other embodiments of trenches disclosed herein to provide additional structural support to the metal liners of the trenches disclosed herein.

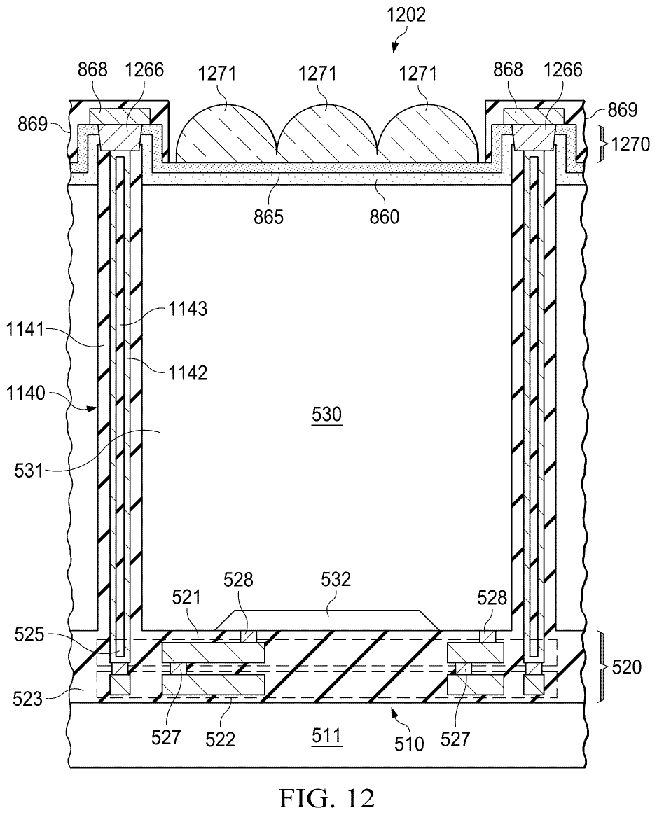

FIG. 12 illustrates a side cross-sectional view of image pixel 1202 in accordance with embodiments of the present disclosure. Image pixel 1202 may be a SPAD-based image pixel and may also be referred to as SPAD-based image pixel 1202. Although a single instance of image pixel 1002 is illustrated in FIG. 12, image pixel 1202 may be one of a plurality of image pixels in an array. For example, image pixel 1202 may represent an embodiment of each of the plurality of SPAD-based image pixels 202 in array 120 of SPAD-based semiconductor device 14 described above with reference to FIG. 3. And in embodiments where SPAD-based semiconductor device 14 is implemented with an array of SiPMs, multiple instances of SPAD-based image pixel 1202 may be grouped together to form each SiPM in the array.

Image pixel 1202 may be formed in a similar manner to image pixel 1102 described above with reference to FIG. 11, but with certain features as described directly below. For example, as shown in FIG. 12, a portion of oxide layer 869 may be removed from the recess between opposing ends of trench 1140 on the back side of image pixel 1202. Lens layer 1270 may then be formed within the recess between opposing ends of trench 1140 on the back side of image pixel 1202. Thus, lens layer 1270 may be located at least in part at a level below back-side grid 868. As shown in FIG. 12 for example, lens layer may be located fully below the level of back-side grid 868.

Lens layer 1270 may be configured to focus light into semiconductor region 530. For example, lens layer 1270 may include at least one microlens 1271 configured to focus light into semiconductor region 530. Microlenses 1271 may be formed with either an organic or an inorganic material. For example, microlenses 1271 may in some embodiments be formed with an inorganic oxide material. In other embodiments, microlenses 1271 may be formed with an organic material, such as an acrylic-based polymer. The upper surface of each microlens 1271 may have a spherical convex shape. Microlenses 1271 may thus refract the light received by image pixel 1202 and focus that light into the semiconductor region 530 of image pixel 1202.

In addition, image pixel 1202 may include a metal contact 1266. In some embodiments, metal contact 1266 may be comprised of the same type of metal material as metal liner 1142. For example, metal contact 1266 may comprise at least one of tungsten and copper. As shown in FIG. 12, metal contact 1266 may have a contact width that is greater than the width of metal liner 1142. Further, as shown in FIG. 12, back-side grid 868 may have a grid width that is greater than a trench width of trench 1140.

The configuration of image pixel 1202, with lens layer 1270 located in the recess between opposing ends of trench 1140 on the back side of image pixel 1202, may further improve crosstalk between neighboring instances of image pixel 1202. Specifically, with lens layer 1270 located in the recess between opposing ends of trench 1140 on the back side of image pixel 1202, the metal liner 1142, metal contact 1266, and back-side grid 868 may form a barrier to block secondary photons generated in semiconductor region 530 from reflecting off the upper surface of semiconductor region 530, passivation layer 860, buffer layer 865, or lens layer 1270, and into a neighboring image pixel.

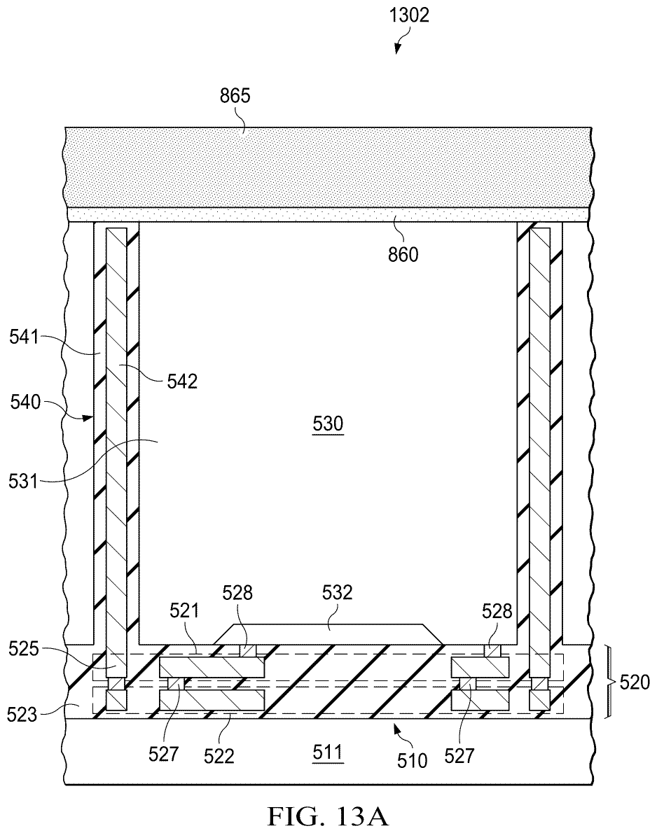

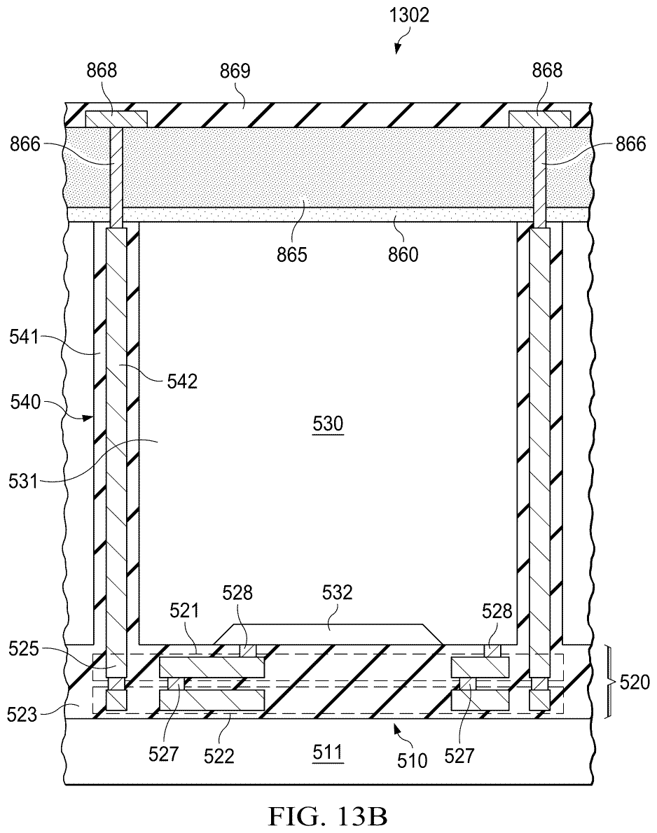

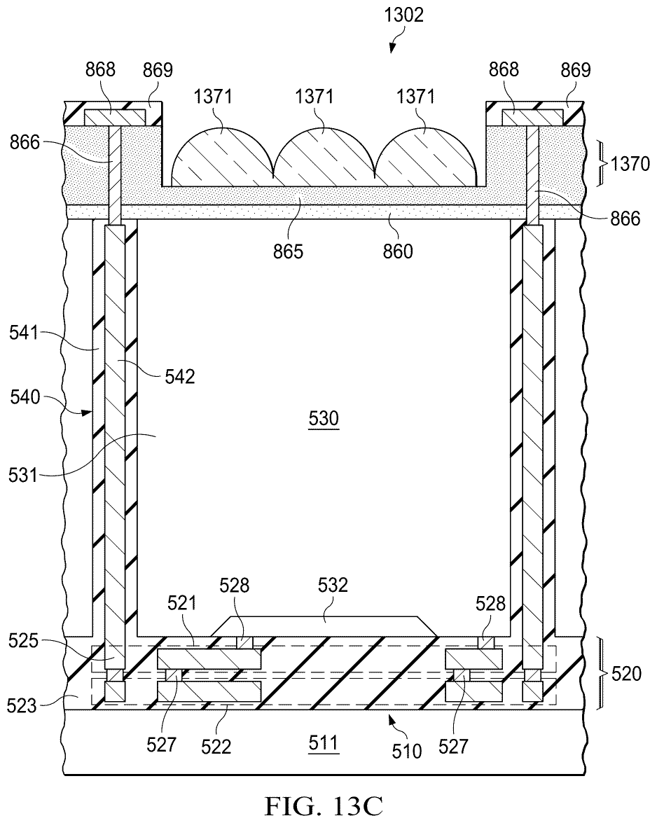

FIGS. 13A-13C illustrate side cross-sectional views of image pixel 1302 at different stages of back-side processing utilized to form image pixel 1302 in accordance with embodiments of the present disclosure.

Image pixel 1302 may be a SPAD-based image pixel and may also be referred to as SPAD-based image pixel 1302. Although a single instance of image pixel 1302 is illustrated in FIGS. 13A-13C, image pixel 1302 may be one of a plurality of image pixels in an array. For example, image pixel 1302 may represent an embodiment of each of the plurality of SPAD-based image pixels 202 in array 120 of SPAD-based semiconductor device 14 described above with reference to FIG. 3. And in embodiments where SPAD-based semiconductor device 14 is implemented with an array of SiPMs, multiple instances of SPAD-based image pixel 1302 may be grouped together to form each SiPM in the array.

Image pixel 1302 may be a back-side illuminated image pixel. For example, during manufacture, various semiconductor processing steps may be applied to the front side 510 of semiconductor region 530. N-type doping may be added to form n-type doping region 532 within the p-type epitaxial region 531 of semiconductor region 530, thereby forming the single-photon avalanche diode. Additional processing steps may be applied to the front side 510 of semiconductor region 530 to form front-side dielectric stack 520 and trench 540. Subsequently, front side 510 may be stacked on an additional substrate 511, which may provide structural support and/or may include corresponding control and readout circuitry to which the metal routing in front-side dielectric stack 520 may be coupled. Additional processing may then be applied to the back side of semiconductor region 530 as described below with reference to FIGS. 13A-13C.

The initial back-side processing steps for image pixel 1302 may be similar to those described above for image pixel 802 with reference to FIGS. 8A and 8B. Specifically, semiconductor region 530 may be etched and/or polished to a level, where the upper surface of semiconductor region 530 is even with an upper end of trench 540. As shown in FIG. 13A, passivation layer 860 and buffer layer 865 may be added over semiconductor region 530 and trench 540. Passivation layer 860 may be formed with a high-k dielectric. For example, passivation layer 860 may include layers of one or more of aluminum oxide, hafnium oxide, and/or tantalum oxide. In some embodiments, buffer layer 865 may be formed with an oxide material such as silicon dioxide. Buffer layer 865 may thus be added above passivation layer 860 by, for example, deposition. In some embodiments, buffer layer 865 may initially be formed with a height that, as described below with reference to FIG. 13C, may provide sufficient space for a recess in which the lens layer may be located. For example, in some embodiments, buffer layer 865 may be initially formed with a height in the range of 100 nm to 1 μm, or any other height suitable to provide sufficient space for a recess in which the lens layer may be located.

Moving to FIG. 13B, metal contact 866 and back-side grid 868 may be added to the back side of image pixel 1302 in a similar manner as described above for image pixel 802 with reference to FIG. 8D. In some embodiments, a hole may be etched through buffer layer 865, passivation layer 860, and dielectric wall 541 of trench 540. The hole may then be filled with a metal material to form metal contact 866. In some embodiments, metal contact 866 may be comprised of the same type of metal material as metal liner 542. For example, metal contact 866 may comprise at least one of tungsten and copper. As shown in FIG. 13B, further metal patterning may be performed on upper surface of image pixel 1302. For example, metal lines may be formed above the metal contacts 866 to form back-side grid 868. In some embodiments, back-side grid 868 may follow the form of trench 540 in a square pattern around each instance of image pixel 1302 from a top-side or bottom-side view perspective, thus forming a grid pattern across the top side of an image-pixel array. In some embodiments, back-side grid 868 may be placed over and in contact with metal contact 866. Back-side grid 868 may thus be electrically coupled to metal liner 542 of trench 540. In some embodiments, metal liner 542 may in turn be coupled to ground through metal routing in first metal layer 521 and/or second metal layer 522 of front-side dielectric stack 520. In addition, an oxide layer 869 may be added above buffer layer 865 and above back-side grid 868. In some embodiments, oxide layer 869 may comprise silicon dioxide.

Moving to FIG. 13C, a portion of oxide layer 869 and buffer layer 865 may be etched to form a recess between opposing metal contacts 866. Lens layer 1370 may then be formed above a lower portion of buffer layer 865 and within the recess between opposing metal contacts 866 on the back side of image pixel 1302. Thus, lens layer 1370 may be located in a recess of buffer layer 865 and at least in part below a level of back-side grid 868. As shown in FIG. 13 for example, lens layer 1370 may be located fully below the level of back-side grid 868.

Lens layer 1370 may be configured to focus light into semiconductor region 530. For example, lens layer 1370 may include at least one microlens 1371 configured to focus light into semiconductor region 530. Microlenses 1371 may be formed with either an organic or an inorganic material. For example, microlenses 1371 may in some embodiments be formed with an inorganic oxide material. In other embodiments, microlenses 1371 may be formed with an organic material, such as an acrylic-based polymer. The upper surface of each microlens 1371 may have a spherical convex shape. Microlenses 1371 may thus refract the light received by image pixel 1302 and focus that light into the semiconductor region 530 of image pixel 1302.

The configuration of image pixel 1302, with lens layer 1370 located in the recess between opposing metal contacts 866 on the back side of image pixel 1302, may further improve crosstalk between neighboring instances of image pixel 1302. Specifically, with lens layer 1370 located in the recess between opposing metal contacts 866, the metal liner 542, metal contact 866, and back-side grid 868 may form a barrier to block secondary photons generated in semiconductor region 530 from reflecting off the upper surface of semiconductor region 530, passivation layer 860, buffer layer 865, or lens layer 1370, and into a neighboring image pixel.

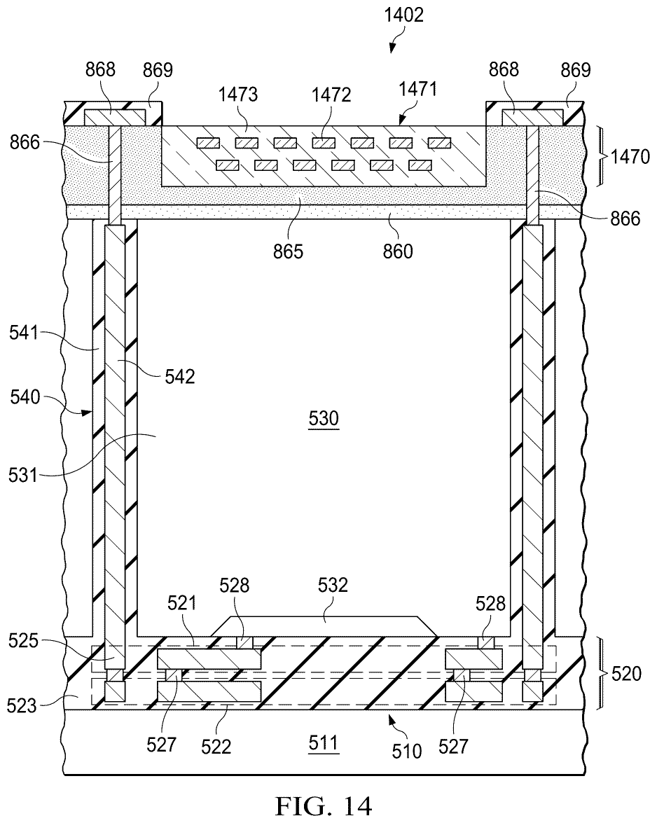

FIG. 14 illustrates a side cross-sectional view of image pixel 1402 in accordance with embodiments of the present disclosure. Image pixel 1402 may be a SPAD-based image pixel and may also be referred to as SPAD-based image pixel 1402. Although a single instance of image pixel 1402 is illustrated in FIG. 14, image pixel 1402 may be one of a plurality of image pixels in an array. For example, image pixel 1402 may represent an embodiment of each of the plurality of SPAD-based image pixels 202 in array 120 of SPAD-based semiconductor device 14 described above with reference to FIG. 3. And in embodiments where SPAD-based semiconductor device 14 is implemented with an array of SiPMs, multiple instances of SPAD-based image pixel 1402 may be grouped together to form each SiPM in the array.

Image pixel 1402 may be formed in a similar manner as image pixel 1302 described above with reference to FIGS. 13A-13C, but with certain features as described directly below. For example, image pixel 1402 may include lens layer 1470. Lens layer 1470 may be formed above a lower portion of buffer layer 865 and within the recess between opposing metal contacts 866 on the back side of image pixel 1402. Thus, lens layer 1470 may be located in a recess of buffer layer 865 and at least in part below a level of back-side grid 868. As shown in FIG. 14 for example, lens layer 1470 may be located fully below the level of back-side grid 868.

Lens layer 1470 may include nanophotonic lens 1471. Nanophotonic lens 1471 may include a plurality of nanostructures 1472 disposed within lens dielectric 1473. The plurality of nanostructures 1472 may be designed and implemented as three-dimensional structures, such as cuboids, having different sizes and having varying indices of refraction compared to the dielectric material of lens dielectric 1473. In some embodiments, the plurality of nanostructures 1472 may be arranged in multiple layers within lens dielectric 1473. Each of the plurality of nanostructures 1472 may have a first refractive index that may be greater than a second refractive index of lens dielectric 1473. For example, lens dielectric 1473 may comprise silicon dioxide. In such embodiments, the plurality of nanostructures 1472 arranged within lens dielectric 1473 may comprise one or more of silicon nitride and titanium dioxide, which have a higher refractive index than silicon dioxide.

The plurality of nanostructures 1472 may be arranged within lens dielectric 1473 to direct light received by image pixel 1402 into semiconductor region 530. As light passes through nanophotonic lens 1471, the light may be refracted and diffracted by the nanostructures 1472 due to the different refractive indexes of lens dielectric 1473 and nanostructures 1472. Light may be directed by nanophotonic lens 1471 to areas where the phases of wavelengths of refracted and diffracted light from different nanostructures 1472 align and therefore constructively interfere with each other. Conversely, light may be diffused and directed away from areas where wavelengths of refracted and diffracted light from different nanostructures 1472 are out of phase with each other and therefore destructively interfere with each other.

The configuration of image pixel 1402, with lens layer 1470 located in the recess between opposing metal contacts 866 on the back side of image pixel 1402, may improve crosstalk between neighboring instances of image pixel 1402. Specifically, with lens layer 1470 located in the recess between opposing metal contacts 866, the metal liner 542, metal contact 866, and back-side grid 868 may form a barrier to block secondary photons generated in semiconductor region 530 from reflecting off the upper surface of semiconductor region 530, passivation layer 860, buffer layer 865, or components of nanophotonic lens 1471, and into a neighboring image pixel.

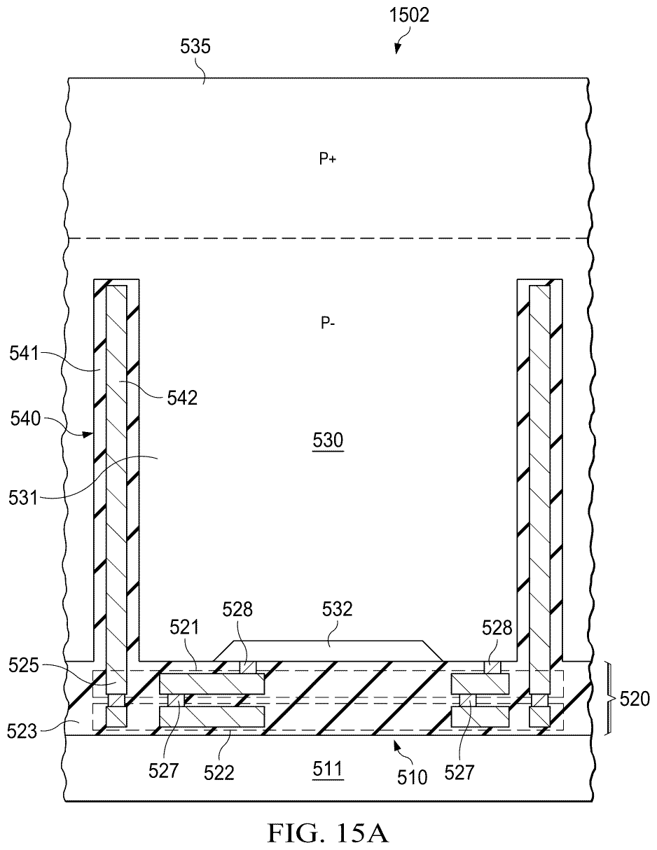

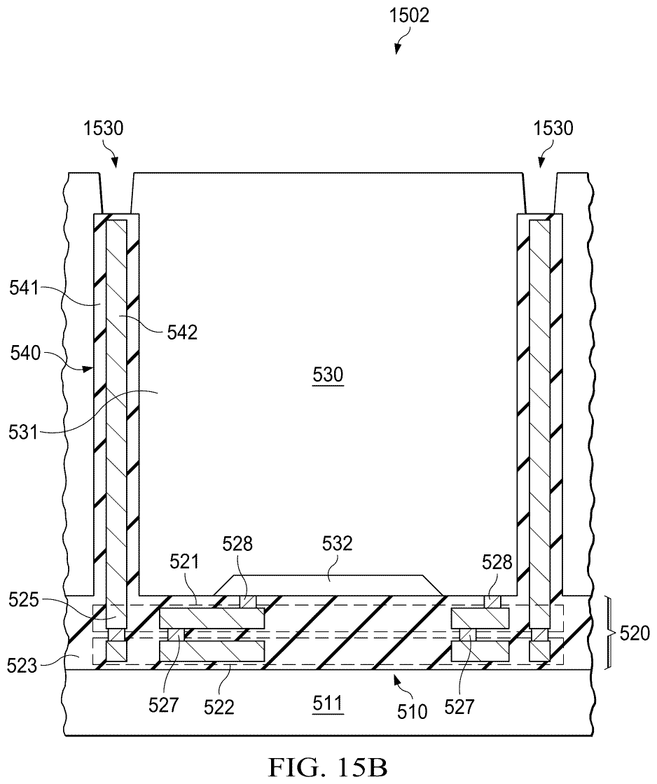

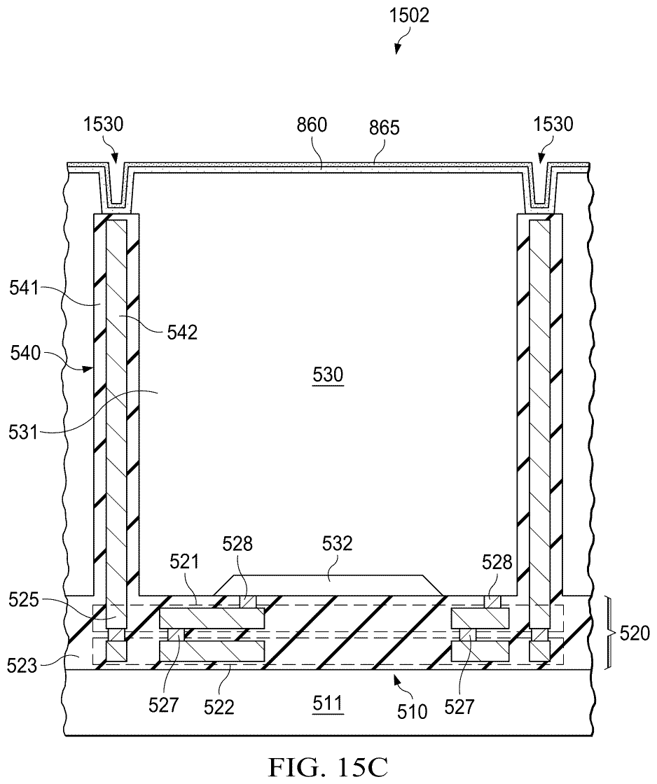

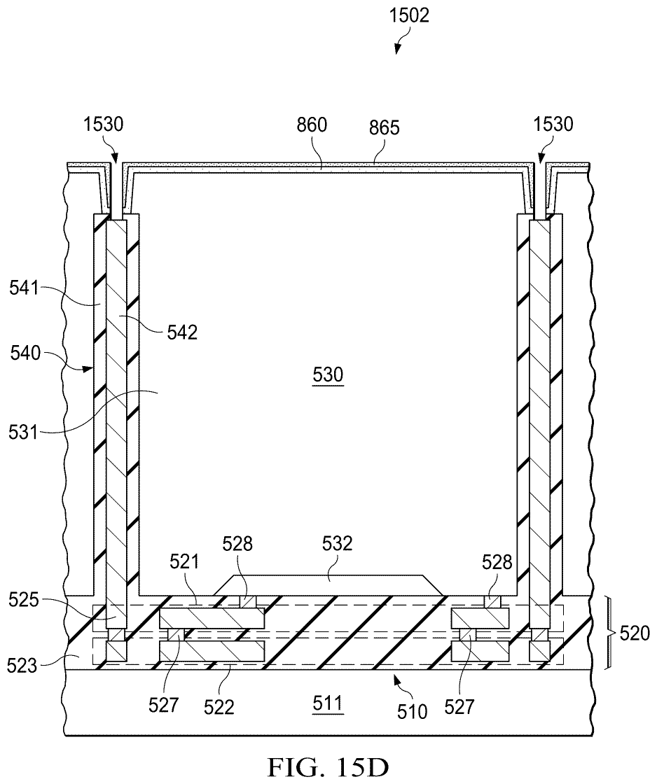

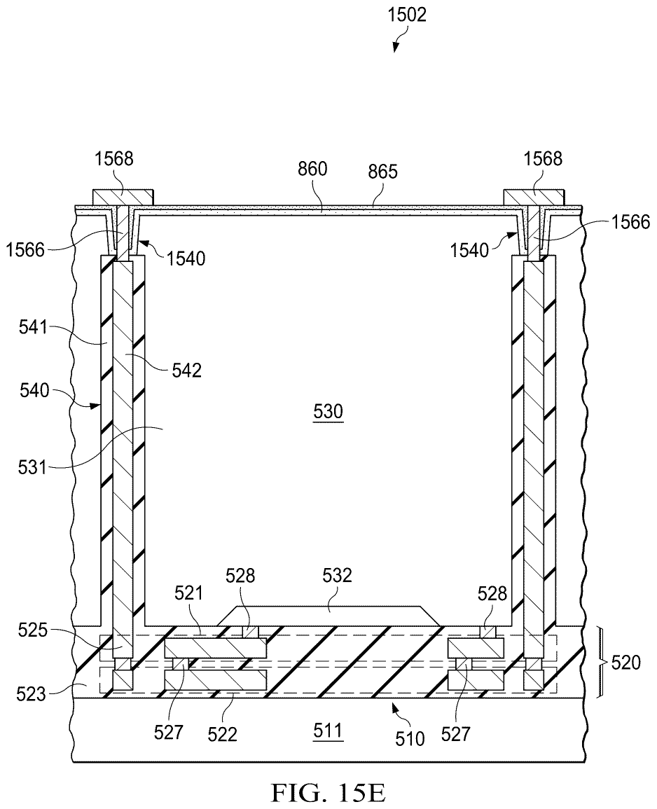

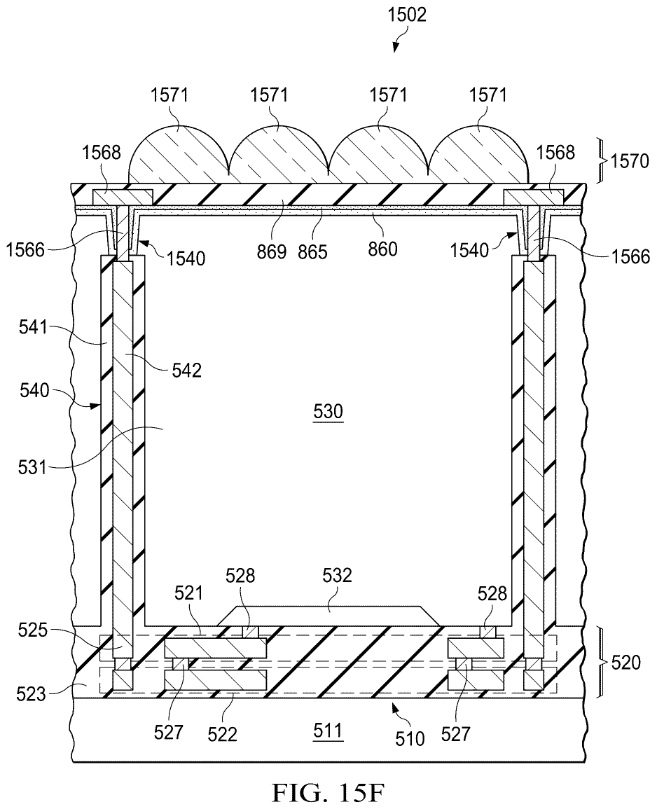

FIGS. 15A-15F illustrate side cross-sectional views of image pixel 1502 at different stages of back-side processing utilized to form image pixel 1502 in accordance with embodiments of the present disclosure.

Image pixel 1502 may be a SPAD-based image pixel and may also be referred to as SPAD-based image pixel 1502. Although a single instance of image pixel 1502 is illustrated in FIGS. 15A-15F, image pixel 1502 may be one of a plurality of image pixels in an array. For example, image pixel 1502 may represent an embodiment of each of the plurality of SPAD-based image pixels 202 in array 120 of SPAD-based semiconductor device 14 described above with reference to FIG. 3. And in embodiments where SPAD-based semiconductor device 14 is implemented with an array of SiPMs, multiple instances of SPAD-based image pixel 1502 may be grouped together to form each SiPM in the array.

Image pixel 1502 may be a back-side illuminated image pixel. For example, during manufacture, various semiconductor processing steps may be applied to the front side 510 of semiconductor region 530. N-type doping may be added to form n-type doping region 532 within the p-type epitaxial region 531 of semiconductor region 530, thereby forming the single-photon avalanche diode. Additional processing steps may be applied to the front side 510 of semiconductor region 530 to form front-side dielectric stack 520 and trench 540. Because trench 540 may be formed from the front side, trench 540 may also be referred to herein as front-side trench 540. After the formation of front-side dielectric stack 520 and front-side trench 540, front side 510 may be stacked on an additional substrate 511, which may provide structural support and/or may include corresponding control and readout circuitry to which the metal routing in front-side dielectric stack 520 may be coupled. Additional processing may then be applied to the back side of semiconductor region 530 as described below with reference to FIGS. 15A-15F.

As shown in FIG. 15A, the back side may initially include semiconductor substrate 535. Various etching and polishing steps, similar to those described above with reference to FIG. 6A, may be applied to the back side to remove semiconductor substrate 535. In some embodiments, semiconductor region 530 may be further etched and/or polished, but to a level where the upper surface of semiconductor region 530 remains above an upper end of front-side trench 540. Front-side trench 540 may thus extend from at least first metal layer 521 into semiconductor region 530 at a level such that the upper surface of semiconductor region 530 remains above an upper end of front-side trench 540.

Moving to FIG. 15B, further patterned etching may be applied to semiconductor region 530 to form hole 1530 in semiconductor region 530 between the upper surface of semiconductor region 530 and the upper end of trench 540. As described in further detail below with reference to FIGS. 15C-15E, the space vacated by hole 1530 may be utilized to form a back-side trench coupled to the front-side trench 540.

Moving to FIG. 15C, passivation layer 860 and buffer layer 865 may be added over the upper surface of semiconductor region 530. Passivation layer 860 may be located above semiconductor region 530 and may be formed with a high-k dielectric. For example, passivation layer 860 may include layers of one or more of aluminum oxide, hafnium oxide, and/or tantalum oxide. Buffer layer 865 may be located above passivation layer 860, and may be formed, for example, by deposition of an oxide material such as silicon dioxide. As shown in FIG. 15C, passivation layer 860 and buffer layer 865 may also line the inner walls of hole 1530.

Moving to FIG. 15D, further patterned etching may be applied to extend hole 1530 down through buffer layer 865, passivation layer 860, and through dielectric wall 541 of trench 540. Then, as shown in FIG. 15E, metal contact 1566 and back-side grid 1568 may be added to the back side of image pixel 1502. Specifically, a metal material, such as tungsten or copper may be deposited in hole 1530 to form metal contact 1566. Thus, the portions of passivation layer 860 and buffer layer 865 lining hole 1530, may in combination with metal contact 1566, collectively form back-side trench 1540 extending from the back-side grid 1568 to an upper end of front-side trench 540. Specifically, back-side trench 1540 may include metal contact 1566 coupling back-side grid 1568 to metal liner 542 of front-side trench 540.

As shown in FIG. 15E, further metal patterning may be performed on upper surface of image pixel 1502 form back-side grid 1568 over metal contact 1566. For example, metal lines may be formed above metal contact 1566 to form back-side grid 1568. In some embodiments, back-side grid 1568 may follow the form of front-side trench 540 and back-side trench 1540 in a square pattern around each instance of image pixel 1502 from a top-side or bottom-side view perspective, thus forming a grid pattern across the top side of an image-pixel array. As shown in FIG. 15E, back-side grid 1568 may in some embodiments be coupled to metal contact 1566. Back-side grid 1568 may thus be electrically coupled by metal contact 1566 to metal liner 542 of trench 540. In some embodiments, metal liner 542 may in turn be coupled to ground through metal routing in first metal layer 521 and/or second metal layer 522 of front-side dielectric stack 520.

Moving to FIG. 15F, an oxide layer 869 may be added above buffer layer 865 and above back-side grid 1568. In some embodiments, oxide layer 869 may comprise silicon dioxide. The upper surface of oxide layer 869 may be planarized, and lens layer 1570 may be formed on the upper surface of oxide layer 869.

As shown in FIG. 15F for example, lens layer 1570 may be located above oxide layer 869 and buffer layer 865 and configured to focus light into semiconductor region 530. In some embodiments, lens layer 1570 may include at least one microlens 1571 configured to focus light into semiconductor region 530. Microlenses 1571 may be formed with either an organic or an inorganic material. For example, microlenses 1571 may in some embodiments be formed with an inorganic oxide material. In other embodiments, microlenses 1571 may be formed with an organic material, such as an acrylic-based polymer. The upper surface of each microlens 1571 may have a spherical convex shape. Microlenses 1571 may thus refract the light received by image pixel 1502 and focus that light into the semiconductor region 530 of image pixel 1502.

As shown in FIG. 15F, and as implemented in image pixel 1502, front-side trench 540 may extend from first metal layer 521 disposed in front-side dielectric stack 520 and into semiconductor region 530. As also shown in FIG. 15F, back-side trench 1540 may include metal contact 1566 coupling back-side grid 1568 to metal liner 542 of front-side trench 540. As described above, metal liner 542 and metal contact 1566 may comprise at least one of tungsten and copper. Metal liner 542 and metal contact 1566 may thus block secondary photons generated in semiconductor region 530 from reflecting off the upper surface of semiconductor region 530, passivation layer 860, or buffer layer 865, and into a neighboring image pixel. The configuration of front-side trench 540, back-side trench 1540 including metal contact 1566, as well as back-side grid 1568, may thus reduce the amount of cross-talk between neighboring instances of image pixel 1502 induced by secondary photons generated in semiconductor region 530.

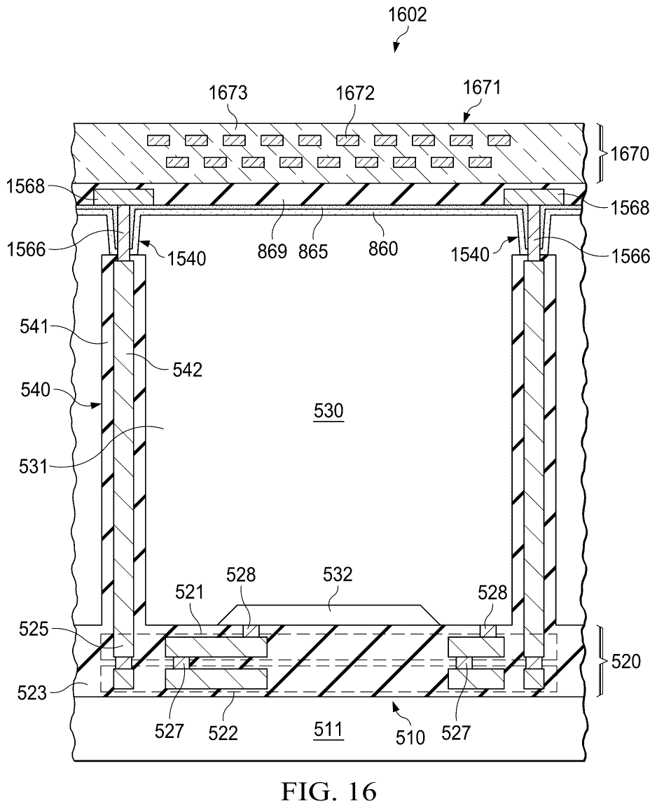

FIG. 16 illustrates a side cross-sectional view of image pixel 1602 in accordance with embodiments of the present disclosure. Image pixel 1602 may be a SPAD-based image pixel and may also be referred to as SPAD-based image pixel 1602. Although a single instance of image pixel 1602 is illustrated in FIG. 16, image pixel 1602 may be one of a plurality of image pixels in an array. For example, image pixel 1602 may represent an embodiment of each of the plurality of SPAD-based image pixels 202 in array 120 of SPAD-based semiconductor device 14 described above with reference to FIG. 3. And in embodiments where SPAD-based semiconductor device 14 is implemented with an array of SiPMs, multiple instances of SPAD-based image pixel 1602 may be grouped together to form each SiPM in the array.

Image pixel 1602 may be formed in a similar manner as image pixel 1502 described above with reference to FIGS. 15A-15F, but with certain features as described directly below. For example, image pixel 1602 may include lens layer 1670. Lens layer 1670 may include nanophotonic lens 1671. Nanophotonic lens 1671 may include a plurality of nanostructures 1672 disposed within lens dielectric 1673. The plurality of nanostructures 1672 may be designed and implemented as three-dimensional structures, such as cuboids, having different sizes and having varying indices of refraction compared to the dielectric material of lens dielectric 1673. In some embodiments, the plurality of nanostructures 1672 may be arranged in multiple layers within lens dielectric 1673. Each of the plurality of nanostructures 1672 may have a first refractive index that may be greater than a second refractive index of lens dielectric 1673. For example, lens dielectric 1673 may comprise silicon dioxide. In such embodiments, the plurality of nanostructures 1672 arranged within lens dielectric 1673 may comprise one or more of silicon nitride and titanium dioxide, which have a higher refractive index than silicon dioxide.

The plurality of nanostructures 1672 may be arranged within lens dielectric 1673 to direct light received by image pixel 1602 into semiconductor region 530. As light passes through nanophotonic lens 1671, the light may be refracted and diffracted by the nanostructures 1672 due to the different refractive indexes of lens dielectric 1673 and nanostructures 1672. Light may be directed by nanophotonic lens 1671 to areas where the phases of wavelengths of refracted and diffracted light from different nanostructures 1672 align and therefore constructively interfere with each other. Conversely, light may be diffused and directed away from areas where wavelengths of refracted and diffracted light from different nanostructures 1672 are out of phase with each other and therefore destructively interfere with each other.

Although examples have been described above, other modifications and variations may be made from this disclosure without departing from the spirit and scope of these examples. The above descriptions of various embodiments illustrate the principles of the invention. Numerous variations and modifications will become apparent to those skilled in the art based on the above disclosure. The following claims are intended to embrace all such variations and modifications.

What is claimed is:

1. A semiconductor device comprising:
a plurality of image pixels, each image pixel of the plurality of image pixels comprising:
a semiconductor region;
a photodiode formed in the semiconductor region;
a front-side dielectric stack comprising at least a first metal layer disposed in a front-side dielectric;
a trench extending from at least the first metal layer disposed in the front-side dielectric stack to at least an upper surface of the semiconductor region, wherein the trench includes a dielectric wall and a metal liner interior to the dielectric wall;
a passivation layer located above the semiconductor region;
a back-side grid located above the passivation layer and electrically coupled to the metal liner of the trench; and
a lens layer located above the passivation layer and configured to focus light into the semiconductor region.

2. The semiconductor device of claim 1, further comprising a plurality of scattering structures formed at the upper surface of the semiconductor region.

3. The semiconductor device of claim 1, wherein the trench extends above the upper surface of the semiconductor region.

4. The semiconductor device of claim 3, wherein the lens layer is located at least in part below a level of the back-side grid.

5. The semiconductor device of claim 1, wherein the photodiode is a single-photon avalanche diode.

6. The semiconductor device of claim 1, wherein the metal liner comprises at least one of tungsten and copper.

7. The semiconductor device of claim 1, wherein the trench further includes a dielectric liner surrounded by the metal liner.

8. The semiconductor device of claim 1, further including a metal contact extending from the back-side grid to the metal liner of the trench.

9. The semiconductor device of claim 8, wherein:
an end of the trench includes a polysilicon filler; and
the metal contact extends through the polysilicon filler to the metal liner of the trench.

10. The semiconductor device of claim 1, wherein the back-side grid has a grid width that is greater than a trench width of the trench.

11. The semiconductor device of claim 1, wherein the lens layer comprises a nanophotonic lens including a plurality of nanostructures disposed within a lens dielectric.

12. The semiconductor device of claim 1, wherein the lens layer comprises at least one microlens configured to focus light into the semiconductor region.

13. A semiconductor device comprising:
a plurality of image pixels, each image pixel of the plurality of image pixels comprising:
a semiconductor region;
a photodiode formed in the semiconductor region;
a front-side dielectric stack comprising at least a first metal layer disposed in a front-side dielectric;
a trench extending from at least the first metal layer disposed in the front-side dielectric stack to an upper surface of the semiconductor region, wherein the trench includes a dielectric wall and a metal liner interior to the dielectric wall;
a passivation layer located above the semiconductor region;
a buffer layer located above the passivation layer;
a back-side grid located above the buffer layer;
a metal contact extending from the back-side grid to the metal liner of the trench; and
a lens layer located in a recess of the buffer layer and at least in part below a level of the back-side grid.

14. The semiconductor device of claim 13, wherein the lens layer is located fully below the level of the back-side grid.

15. The semiconductor device of claim 13, wherein the lens layer comprises at least one microlens configured to focus light into the semiconductor region.

16. The semiconductor device of claim 13, wherein the lens layer comprises a nanophotonic lens including a plurality of nanostructures disposed within a lens dielectric.

17. A semiconductor device comprising:
a plurality of image pixels, each image pixel of the plurality of image pixels comprising:
a semiconductor region;
a photodiode formed in the semiconductor region;
a front-side dielectric stack comprising at least a first metal layer disposed in a front-side dielectric;
a front-side trench extending from at least the first metal layer disposed in the front-side dielectric stack into the semiconductor region, wherein the front-side trench includes a dielectric wall and a metal liner interior to the dielectric wall;
a passivation layer located above the semiconductor region;
a back-side grid located above the passivation layer;
a back-side trench extending from the back-side grid to an upper end of the front-side trench, the back-side trench including a metal contact coupling the back-side grid to the metal liner of the front-side trench; and
a lens layer located above the passivation layer and configured to focus light into the semiconductor region.

18. The semiconductor device of claim 17, the back-side grid comprises tungsten.

19. The semiconductor device of claim 17, wherein the metal liner comprises at least one of copper and tungsten.

20. The semiconductor device of claim 17, wherein the lens layer comprises a nanophotonic lens including a plurality of nanostructures disposed within a lens dielectric.
